(19) United States
(12) Patent Application Publication
(10) Pub. No.: US 2026/0362919 A1
(43) Pub. Date: Nov. 12, 2026

(54) DISPLAY PANEL AND DISPLAY APPARATUS

(71) Applicant: Xiamen Tianma Display Technology Co., Ltd., Xiamen (CN)

(72) Inventors: Yuancheng Lin, Xiamen (CN); Huomei Hua, Xiamen (CN)

(73) Assignee: Xiamen Tianma Display Technology Co., Ltd., Xiamen (CN)

(21) Appl. No.: 19/409,751

(22) Filed: Dec. 5, 2025

(30) Foreign Application Priority Data
May 8, 2025 (CN) 202510591658.2

(51) Int. Cl. H10K 59/131; H10K 59/121

(52) U.S. Cl. CPC H10K 59/131; H10K 59/1213

(57) ABSTRACT

A display panel and a display apparatus are provided in the present disclosure. The display panel has a first region and a second region. Transmittance of the first region is greater than transmittance of the second region. The second region includes a first sub-region adjacent to the first region in a first direction. The display panel includes first signal lines and pixel circuits. The first signal line is disposed in the second region and includes first sub-segments respectively located at two sides of the first region in a second direction intersecting the first direction, and a first detouring portion connecting the first line segments with each other. The first detouring portion includes a second sub-segment extending in the second direction and at least partially located in the first sub-region. The pixel circuits are disposed in the second region and arranged in an array along the first and second directions.

### CROSS REFERENCE TO RELATED APPLICATIONS

This application claims priority to Chinese Patent Application No. 202510591658.2, titled “DISPLAY PANEL AND DISPLAY APPARATUS” and filed on May 8, 2025, which is hereby incorporated by reference in its entirety.

### TECHNICAL FIELD

The present disclosure relates to the technical field of the display device, and in particular to a display panel and a display apparatus.

### BACKGROUND

In display apparatus, the display panel is provided with an aperture to form a photosensitive functional region considering that the photosensitive components such as the front camera, the fingerprint recognition element, and the infrared sensing element need to be integrated. In this way, external light can enter the light-sensitive components below the display panel through the photosensitive functional region on the display panel. However, the photosensitive functional region will affect the internal trace layout of the display panel.

### SUMMARY

The present disclosure provides a display panel and a display apparatus, which can meet the trace layout requirement.

In a first aspect, some embodiments of the present disclosure provide a display panel. The display panel has a first region and a second region, transmittance of the first region is greater than transmittance of the second region, and the second region including a first sub-region adjacent to the first region in a first direction. The display panel includes first signal lines and pixel circuits. The first signal lines are disposed in the second region. The first signal lines each includes first sub-segments respectively located at two sides of the first region along a second direction intersecting the first direction, and a first detouring portion connecting the first sub-segments with each other. The first detouring portion includes a second sub-segment extending in the second direction and at least partially located in the first sub-region. The pixel circuits are disposed in the second region and arranged in an array in the first direction and the second direction, at least two of the pixel circuits arranged side by side in the second direction jointly form a circuit column of circuit columns, and at least two adjacent ones of the second sub-segments of the first signal lines respectively overlap adjacent circuit columns of the circuit columns in a thickness direction of the display panel.

In a second aspect, some embodiments of the present disclosure provide a display apparatus including the display panel described in the first aspect.

According to the display panel and the display apparatus provided by the embodiments of the present disclosure, at least two adjacent second sub-segments respectively overlap adjacent circuit columns in the thickness direction of the display panel, that is, there are at least two adjacent second sub-segments between projections of which there is no projection of one corresponding circuit column. Such design reduces a spacing between adjacent second sub-segments and increases a distribution density of multiple second sub-segments in a unit area. On such basis, more second sub-segments can be integrated into a region with a smaller area, so that more second sub-segments are disposed in the first sub-region and disposed in a same layer, thereby reducing the space occupied by the second sub-segments in other regions or layers, and thus meeting the trace layout requirement.

### BRIEF DESCRIPTION OF THE DRAWINGS

To more clearly describe the technical solutions of the embodiments of the present disclosure, a brief introduction to the figures used in the embodiments of the present disclosure is presented in the following. For those skilled in the art, other figures can be obtained based on these figures without creative efforts.

FIG. 1 is a schematic diagram of a display panel provided by some embodiments of the present disclosure;

FIG. 2 is a simplified partial schematic diagram of another display panel provided by some embodiments of the present disclosure;

FIG. 3 is a partial schematic diagram of FIG. 2;

FIG. 4 is a simplified partial schematic diagram of another display panel provided by some embodiments of the present disclosure;

FIG. 5 is a circuit schematic diagram of a pixel circuit in a display panel provided by some embodiments of the present disclosure;

FIG. 6 is a simplified partial schematic diagram of another display panel provided by some embodiments of the present disclosure;

FIG. 7 is a circuit schematic diagram of a pixel circuit in another display panel provided by some embodiments of the present disclosure;

FIG. 8 is a cross-sectional view of a display panel provided by some embodiments of the present disclosure;

FIG. 9 is a cross-sectional view of another display panel provided by some embodiments of the present disclosure;

FIG. 10 is a layout schematic diagram of a display panel provided by some embodiments of the present disclosure;

FIG. 11 is a simplified partial schematic diagram of another display panel provided by some embodiments of the present disclosure;

FIGS. 12A and 12B are two simplified partial schematic diagrams of display panels provided by some embodiments of the present disclosure;

FIG. 13 is a simplified partial schematic diagram of another display panel provided by some embodiments of the present disclosure;

FIG. 14 is a layout schematic diagram of a display panel provided by some embodiments of the present disclosure;

FIG. 15 is a simplified partial schematic diagram of another display panel provided by some embodiments of the present disclosure;

FIG. 16 is a simplified schematic diagram of another display panel provided by some embodiments of the present disclosure;

FIG. 17 is a simplified schematic diagram of another display panel provided by some embodiments of the present disclosure;

FIG. 18 is a simplified schematic diagram of another display panel provided by some embodiments of the present disclosure;

FIGS. 19A and B are simplified diagrams illustrating a relationship between a trace structure and circuit columns in a local region of a display panel provided by some embodiments of the present disclosure;

FIG. 20 is a simplified partial schematic diagram of another display panel provided by some embodiments of the present disclosure;

FIG. 21 is a simplified partial schematic diagram of another display panel provided by some embodiments of the present disclosure;

FIG. 22 is a simplified partial schematic diagram of another display panel provided by some embodiments of the present disclosure;

FIGS. 23A and B are simplified diagrams illustrating a relationship between a trace structure and circuit columns in a local region of a display panel provided by some embodiments of the present disclosure; and

FIG. 24 is a schematic diagram of a display apparatus provided by some embodiments of the present disclosure.

### DESCRIPTION FOR REFERENCE SIGNS

10, First signal line; 11, First sub-segment; 12, First detouring portion; 13, Second sub-segment; 14, Third sub-segment;
200, Circuit column; 20, Pixel circuit;
30, First line segment; 31, First-type trace; 32, Second-type trace; 33, Third-type trace; 34, first trace; 35, second trace;
41. Substrate; 42. First conductor layer; 43. Second conductor layer; 44. Third conductor layer; 45. Fourth conductor layer; 46. Fifth conductor layer; 47. Low-temperature poly-silicon active layer; 48. Oxide active layer;
51. First reset signal line; 52. Second reset signal line; 53. Third reset signal line;
60. Second signal line;
70. Third signal line; 71. Second detouring portion; 72. Fourth sub-segment;
80. Second line segment;
90. Fourth signal line; 91. Third detouring portion; 92. Fifth sub-segment; 93. Sixth sub-segment;
R. Fan-out line;
P. Light-emitting unit;
A1, First region; A2, Second region; A21, First sub-region; A22, Second sub-region; A3, Third region; A31, Fan-out region; and
X, First direction; Y, Second direction; Z, Thickness direction.

### DETAILED DESCRIPTION

Features and exemplary embodiments of various aspects of the present disclosure will be described in detail below. To make the objectives, technical solutions, and advantages of the present disclosure clearer, the following description will be further detailed with reference to the accompanying drawings and specific embodiments. It should be understood that the specific embodiments described herein are merely intended to illustrate the present disclosure but not to limit the present disclosure. For those skilled in the art, the present disclosure can be implemented without some of the specific details described herein. The following description of the embodiments is provided only to provide a better understanding of the present disclosure by illustrating examples thereof.

It should be noted that, in the present document, relational terms such as “first” and “second” are used merely to distinguish one entity or operation from another entity or operation, and do not necessarily require or imply any such actual relationship or order between the entities or operations. Furthermore, the terms “include,” “contain,” or any other variations thereof are intended to encompass non-exclusive inclusion, such that a process, method, an article, or a device that includes a series of elements not only includes those elements but includes other elements not explicitly listed, or elements inherent to such a process, a method, an article, or a device. Unless otherwise limited, the elements defined by the phrase “including...” do not exclude additional identical elements in the process, the method, the article, or the device that includes the specified elements.

To achieve specific photosensitive functions, a photosensitive functional region is provided in the display panel, and at least one of the trace structures will extend to the photosensitive functional region. Typically, to minimize the impact of these traces on photosensitivity and meet the trace layout requirement, the trace structure includes a detour line structure designed to detour round the photosensitive functional region. However, limited to its own design of the display panel, in at least part of the region at a periphery of the photosensitive functional region, there may only be a small spatial dimension available for the detour line structure. Under such circumstances, if conventional line detouring methods are used in this region, it may not be possible to meet the layout space requirements for all detour line structures.

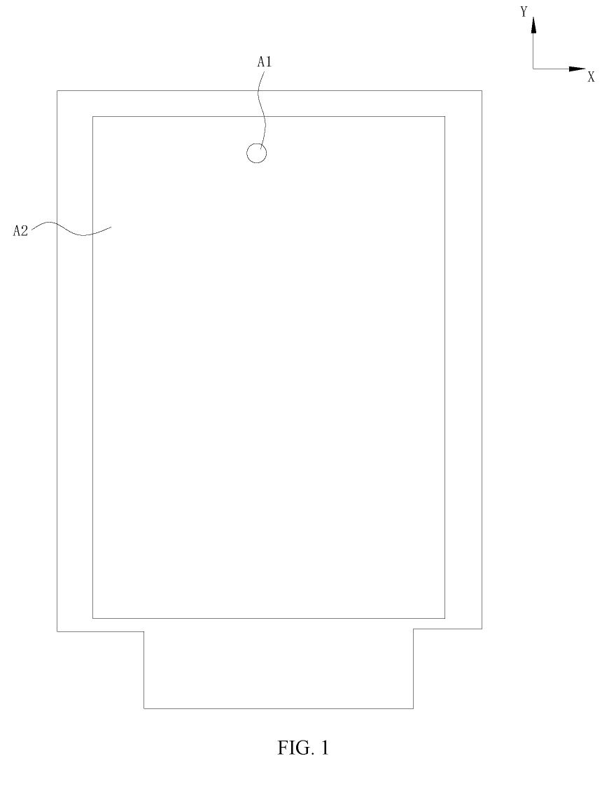

In view of the above problems, in a first aspect, referring to FIGS. 1 - 3, some embodiments of the present disclosure provide a display panel. The display panel has a first region A1 and a second region A2, and the transmittance of the first region A1 is greater than the transmittance of the second region A2. The second region A2 includes a first sub-region A21 adjacent to the first region A1 in a first direction X. The display panel includes a first signal line 10 and a pixel circuit 20, and the first signal line 10 is disposed in the second region A2 and includes first sub-segments 11 respectively located at two sides of the first region A1 in a second direction Y, and a first detouring portion 12 connecting the first sub-segments 11 with each other. The first detouring portion 12 includes a second sub-segment 13 extending in the second direction Y and at least partially located in the first sub-region A21, and the first direction X intersects the second direction Y.

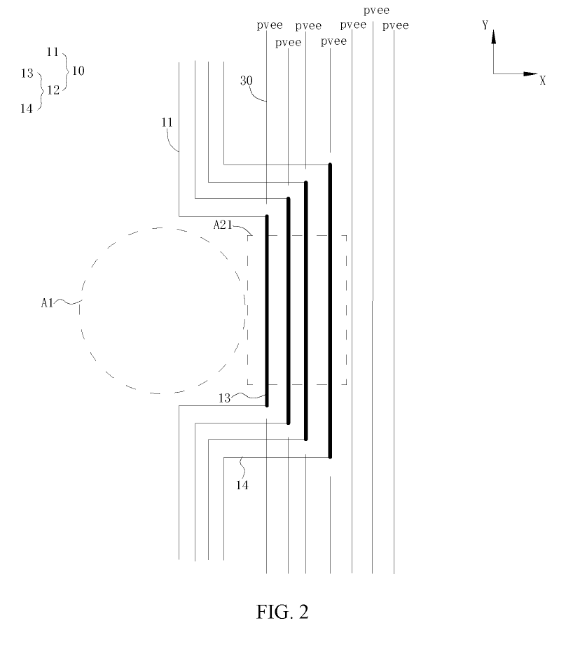

The pixel circuit 20 is located in the second region A2. Multiple pixel circuits 20 are arranged in an array in the first direction X and the second direction Y. Multiple pixel circuits 20 arranged side by side in the second direction Y jointly form a circuit column 200. At least two adjacent second sub-segments 13 respectively overlap adjacent circuit columns 200 in a thickness direction Z of the display panel. In FIG. 2, the first region A1 and the first sub-region A21 are indicated by fine dashed lines, the pixel circuits 20 in the first sub-region A21 are indicated by thick dashed lines, and the second sub-segment 13 is indicated by a thick solid line.

The display panel is used in subsequent preparation for a display apparatus. The display panel is a device configured to achieve a display function. In addition to the display panel, the display apparatus can include photosensitive components such as a front camera, a fingerprint recognition element, and an infrared sensing element. These photosensitive components are disposed on a backlight side of the display panel to achieve specific functions such as fingerprint recognition and under-display camera shooting.

The specific light-emitting method of the display panel and the specific type of display apparatus are not limited in the embodiments of present disclosure. The display panel can include an organic light-emitting functional layer, and in this case, the display apparatus can be an organic light-emitting display apparatus. Alternatively, the display panel can include micro-light-emitting diodes, and in this case, the display apparatus can be a micro-light-emitting display apparatus.

The display panel has the first region A1 and the second region A2. The second region A2 is a primary region of the display panel configured to achieve display function. Taking the display panel including an organic light-emitting functional layer as an example, the organic light-emitting functional layer can include multiple light-emitting units, and at least one of the light-emitting units is located in the second region A2. The first region A1 is the photosensitive functional region of the display panel, and the transmittance of the first region A1 is greater than the transmittance of the second region A2. In the subsequently formed display apparatus, a photosensitive component can be provided on a back surface of the display panel at a position corresponding to the first region A1. Depending on actual requirements, no light-emitting units can be provided in the first region A1, or the light-emitting unit can be provided in the first region A1. That is, the first region A1 can only meet photosensitive requirement without light-emitting function, or the first region A1 can not only meet photosensing requirement but also achieve light-emitting function.

The specific morphology of the first region A1 and the specific morphology of the second region A2, as well as the specific position relationship between the first region A1 and the second region A2, are not limited in the embodiments of present disclosure. For example, the first region A1 can be circular, square, elliptic, or in other regular shape or irregular shape. Similarly, an outer contour of the first region A1 can be circular, square, or in other regular shape or irregular shape, and the second region A2 can surround the first region A1.

The first sub-region A21 is a local region in the second region A2, and the first sub-region A21 is adjacent to the first region A1. Here, “adjacent” refers to that the first sub-region A21 is a region in the second region A2 that is closest to the first region A1 in the first direction X, other regions such as a non-display region can be provided between the first sub-region A21 and the first region A1, or no other regions can be provided between the first sub-region A21 and the first region A1, which is not limited in the embodiments of the present disclosure.

The first sub-region A21 can have various sizes and shapes. For example, the shape of the first sub-region A21 can be the same as the shape of the first region A1, or the first sub-region A21 and the first region A1 can have different shapes. In the figures, the first region A1 is shown as a circular structure, and the first sub-region A21 is shown as a square structure.

The first signal line 10 is a trace structure that configured to transmit specific signals and that needs to extend to detour round the first region A1. The first signal line 10 is located in the first region A1. The first sub-segments 11 are primary parts of the first signal line 10, each extend in the second direction Y, and are respectively located at two sides of the first region A1. The first detouring portion 12 is a part of the first signal line 10 configured to avoid the first region A1. The first detouring portion 12 includes a second sub-segment 13 extending in the second direction Y and is located at a side of the first region A1 in the first direction X. The first direction X can represent a row direction of the display panel, and the second direction Y can represent a column direction of the display panel. Optionally, the first direction X and the second direction Y are perpendicular to each other.

The second sub-segment 13 is at least partially located in the first sub-region A21. Limited to the layout of the display panel, the spatial dimension of the first sub-region A21 is relatively small. On such basis, if multiple second sub-segments 13 of multiple first signal lines 10 are arranged using the layout method in the related art, it is impossible to meet the requirement for disposing all second sub-segments 13 in the first sub-region A21, resulting in that at least one of the first sub-segments 11 needs to be disposed in other regions of the second region A2. Thus, the length of the detour line is increased and space in other regions is occupied, or different first sub-segments 11 are disposed in different layers, thereby occupying internal space in other layers.

In view of the above, in some embodiments of the present disclosure, the positional relationship between the second sub-segment 13 and the pixel circuit 20 is adjusted, so that multiple second sub-segments 13 can be disposed in the first sub-region A21 and disposed in a same layer. Specifically, the pixel circuit 20 is a circuit structure that drives the display panel to achieve its light-emitting function. The pixel circuit 20 includes thin-film transistors and a storage capacitor cst. The pixel circuit 20 can be in various forms, for example, the pixel circuit 20 can have a circuit structure of 7T1C, that is, the pixel circuit 20 includes seven thin-film transistors and one storage capacitor cst, or the pixel circuit 20 can have a circuit structure such as an 8T1C or 8T2C.

Multiple pixel circuits 20 arranged side by side in the second direction Y jointly form a circuit column 200, and multiple circuit columns 200 are arranged side by side in the first direction X. In the embodiments of the present disclosure, at least two adjacent second sub-segments 13 respectively overlap adjacent circuit columns 200 in the thickness direction Z of the display panel, that is, there are at least two adjacent second sub-segments 13 between the projections of which there is no projection of one circuit column 200. Such design reduces the spacing between adjacent second sub-segments 13 and increases the distribution density of multiple second sub-segments 13 in a unit area. On such basis, more second sub-segments 13 can be integrated in a region with a relatively small area, so that the more second sub-segments 13 are all disposed in the first sub-region A21 and in a same layer, thereby reducing the space of other regions or layers that is occupied by the second sub-segments 13, and meeting the trace layout requirement of the display panel.

It should be noted that the “projections of adjacent second sub-segments 13” referred to in the embodiments of present disclosure indicates orthogonal projections of two adjacent second sub-segments 13 on any one plane perpendicular to the thickness direction Z of the display panel, and the “projection of circuit column 200” is interpreted similarly. The term “overlapping” as mentioned in the embodiments of the present disclosure refers to that overlapping regions are respectively formed between the orthogonal projections of the at least two adjacent second sub-segments 13 on any one plane perpendicular to the thickness direction Z of the display panel and the orthogonal projections of the adjacent circuit columns 200 on this plane. Further optionally, any adjacent second sub-segments 13 respectively overlap adjacent circuit columns 200 in the thickness direction Z of the display panel.

Additionally, the “adjacent second sub-segments 13” as mentioned in the embodiments of the present disclosure refers to that no other second sub-segments 13 is provided between the two second sub-segments 13. The “adjacent circuit columns 200” as mentioned in the embodiments of the present disclosure refers to that no other circuit columns 200 is formed between the two circuit columns 200. The “adjacent” as mentioned subsequently in the present disclosure is analogous to the above interpretation and will not be repeated.

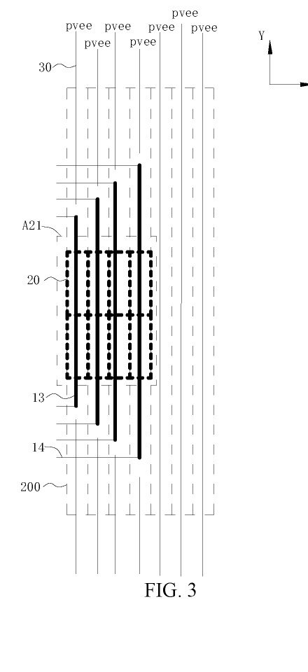

In some embodiments, as shown in FIGS. 1-3, the display panel includes a first line segment 30 located in a same layer as and insulated from the second sub-segment 13. The first line segment 30 extends in the second direction Y, and the first line segments 30 are respectively located at two sides of the second sub-segment 13. The second sub-segment 13 and the first line segment 30 overlap a same circuit column 200 in the thickness direction Z of the display panel.

The first sub-segment 11 is configured to transmit a different signal from the first signal line 10, so the first line segment 30 and the second sub-segment 13 must be insulated from each other. The first line segment 30 and the second sub-segment 13 are located in a same layer, that is, they are made of a same material and are fabricated simultaneously in a same process.

Since the primary structure of the second sub-segment 13 is located in the first sub-region A21, and there is typically a certain distance formed between two edges of the first sub-region A21 and the second region A2 in the second direction, no second sub-segment 13 is provided in a certain region between the edge of the second region A2 and the first sub-region A21 in the second direction A2.

In view of this, the embodiments of the present disclosure add the first line segment 30 in the display panel. The first line segment 30 and the second sub-segment 13 have a same extending direction, and the first line segments 30 are respectively located at two sides of the second sub-segment 13. In this way, different regions of the second region A2 disposed in the second direction Y are provided with same or similar trace structures, thereby reducing display differences caused by different wiring manners and improving the display uniformity of the display panel. Further, the first line segment 30 can also be configured to transmit a specific signal, thereby improving the transmission reliability of the specific signal in the display panel.

It should be noted that for different first line segments 30 arranged side by side in the first direction X, different first line segments 30 can be configured to transmit different signals, or they can also be configured to transmit a same signal, which is not limited in the embodiments of the present disclosure. Optionally, the two first line segments 30 respectively located at two sides of the first sub-region A21 and overlapping a same circuit column 200 are configured to transmit a same signal.

In some embodiments, as shown in FIG. 2, at least one of the first line segments 30 is configured to transmit a first power supply signal pvee.

Taking the display panel including the organic light-emitting functional layer as an example, the organic light-emitting functional layer includes multiple light-emitting units. The display panel typically is provided with a cathode and an anode at two sides of the light-emitting unit, and the cathode and the anode jointly control whether the light-emitting unit emit light. The cathodes of different light-emitting units can be connected to each other, and are configured to receive the first power supply signal pvee.

It should be noted that, according to different internal trace design of the display panel, all first line segments 30 can be configured to transmit the first power supply signal pvee. In this case, all first line segments 30 are configured to transmit a same signal. Alternatively, at least one of the first line segments 30 can be configured to transmit the first power supply signal pvee, while at least one of the first line segments 30 is configured to transmit other signals. In this case, at least two different first line segments 30 are configured to transmit different signals. Of course, all first line segments 30 can be configured to transmit other power supply signals except pvee.

In the embodiments of the present disclosure, the at least two adjacent second sub-segments 13 respectively overlap the adjacent circuit columns 200, so that the spacing between the adjacent second sub-segments 13 is reduced, thereby allowing more second sub-segments 13 to be provided in the first sub-region A21 to meet the layout requirement for multiple second sub-segments 13. On 13ch basis, the embodiments of the present disclosure further provides first line segments 30 respectively located at two sides of the second sub-segment 13 and 13nfigures the first line segments 30 to transmit the first power supply signal pvee. Such design not only improve the display uniformity of the display panel but also improves the transmission reliability of the first power supply signal pvee, thereby further improving the display performance of the display panel.

In some optional embodiments, all first line segments 30 are configured to transmit the first power supply signal pvee. That is, in the embodiments of the present disclosure, the first line segments 30 located at two side of any second sub-segment 13 are configured to transmit the first power supply signal pvee, thereby further improving the transmission reliability of the first power supply signal pvee.

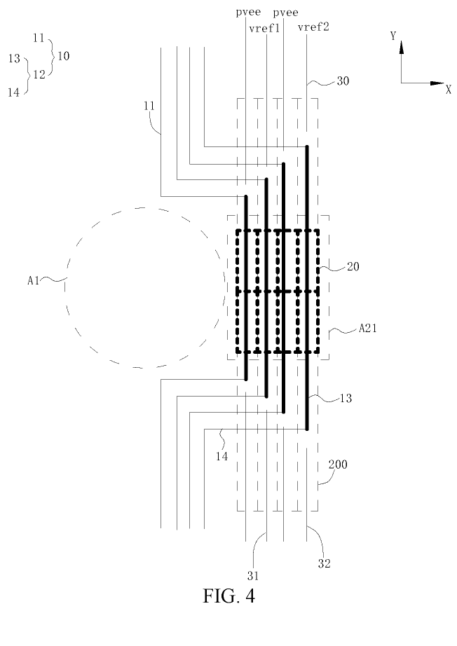

In some embodiments, as shown in FIG. 4, at least one of the first line segments 30 is configured to transmit a reset signal, and the first line segments 30 configured to transmit the first power supply signal pvee and the first line segments 30 configured to transmit the reset signal alternate in the first direction X.

The first power supply signal pvee and the reset signal are both constant-voltage signals. The reset signal is configured to reset a specific node or a specific structure to reset the specific node or the specific structure to its initial state. The reset signal can have various types, for example, at least one of the reset signals is configured to reset the anode, or at least one of the reset signals is configured to reset the first node N1, to reset a lower electrode plate c1 of the storage capacitor cst and a control terminal of the driving transistor M3, or at least one of the reset signals can reset a second node N2 to adjust a bias state of the driving transistor M3. The driving transistor M3 is a thin-film transistor having a driving function in the pixel circuit 20.

In the embodiments of the present disclosure, the first line segments 30 can not only be configured to transmit the first power supply signal pvee but also to transmit the reset signal. Such design not only facilitates to improving the transmission reliability of the first power supply signal pvee but also facilitates to improving the transmission reliability of the reset signal. Among the multiple first line segments 30 configured to transmit the reset signals, all these first line segments 30 can transmit a same type of reset signal, or at least two different first line segments 30 can transmit different types of reset signals.

Further, the first line segments 30 configured to transmit the first power supply signal pvee and the first line segments 30 configured to transmit the reset signal alternate in the first direction X. That is, for any two adjacent first line segments 30, one first line segment 30 is configured to transmit the first power supply signal pvee, and the other first line segment 30 is configured to transmit the reset signal. With such design, the multiple first line segments 30 configured to transmit the first power supply signal pvee can be distributed at intervals in different regions of the display panel disposed in the first direction X, which prevents the excessive concentration of the multiple first line segments 30 configured to transmit the first power supply signal pvee in the first direction X, thereby improving the transmission reliability of the first power supply signal pvee in different regions of the display panel disposed in the first direction X. Similarly, such design also facilitates to improving the transmission reliability of the reset signals in different regions of the display panel disposed in the first direction X.

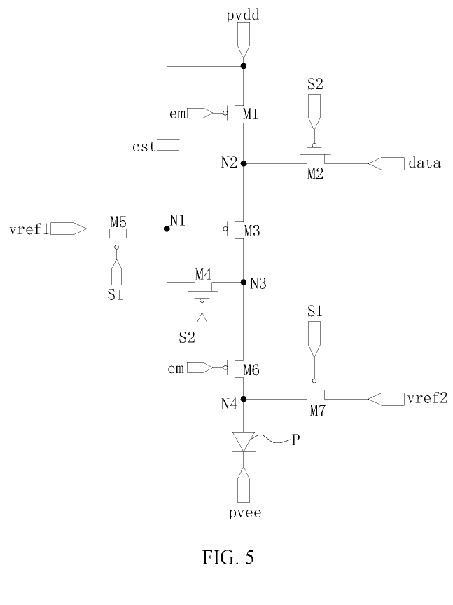

In some embodiments, referring to FIGS. 4 and 5 the multiple first line segments 30 configured to transmit the reset signals include a first-type trace 31 and a second-type trace 32. The first-type trace 31 is configured to transmit a first reset signal vref1, and the second-type trace 32 is configured to transmit a second reset signal vref2. The pixel circuit 20 includes a first reset transistor M5, a second reset transistor M7, and a driving transistor M3. A first electrode of the first reset transistor M5 is configured to receive the first reset signal vref1, and a second electrode of the first reset transistor M5 is electrically connected to the control terminal of the driving transistor M3. A first electrode of the second reset transistor M7 is configured to receive the second reset signal vref2, and a second electrode of the second reset transistor M7 is electrically connected to the anode.

The first reset transistor M5, the second reset transistor M7, and the driving transistor M3 are all thin-film transistors in the pixel circuit 20. The first reset transistor M5 and the second reset transistor M7 are both switching transistors. Each thin-film transistor includes a first electrode, a second electrode, and a control terminal, and the control terminal is configured to control whether the first electrode and the second electrode conduct electricity.

The pixel circuit 20 in the embodiments of the present disclosure can have a circuit structure of 7T1C. In conjunction with the circuit diagrams, it can be seen that the first electrode of the first reset transistor M5 is configured to receive the first reset signal vref1, and the second electrode of the first reset transistor M5 is electrically connected to the first node N1, while the first node N1 is electrically connected to both the control terminal of the driving transistor M3 and the lower electrode plate c1 of the storage capacitor cst. On such basis, the first reset transistor M5 is configured to control whether the first reset signal vref1 is written to the first node N1 and written to both the control terminal of the driving transistor M3 and the lower plate c1 of the storage capacitor cst through the first node N1. Thus, the first reset signal vref1 is a specific signal configured to reset the control terminal of the driving transistor M3 and the lower plate c1 of the storage capacitor cst.

The first electrode of the second reset transistor M7 is configured to receive the second reset signal vref2, and the second electrode of the second reset transistor M7 is electrically connected to the anode. The second reset transistor M7 is configured to control whether the second reset signal vref2 is written to the anode. Thus, the second reset signal vref2 is a specific signal configured to reset the anode.

In the embodiments of the present disclosure, the first line segments 30 configured to transmit the reset signals includes a first-type trace 31 and a second-type trace 32. The first-type trace 31 is configured to transmit the first reset signal vref1 and the second-type trace 32 is configured to transmit the second reset signal vref2, so that both the first reset signal vref1 and the second reset signal vref2 respectively correspond to vertical traces disposed in a same layer as the second sub-segment 13. In this way, not only the transmission reliability of the first reset signal vref1 but also the transmission reliability of the second reset signal vref2 are facilitated to be improved, thereby improving the operational reliability of the pixel circuit 20.

The specific position relationship between multiple first-type traces 31 and multiple second-type traces 32 is not limited in the embodiments of present disclosure. Optionally, multiple first-type traces 31 and multiple second-type traces 32 alternate in the first direction X, that is, one second-type trace 32 is provided between adjacent first-type traces 31, and one first-type trace 31 is provided between adjacent second-type traces 32.

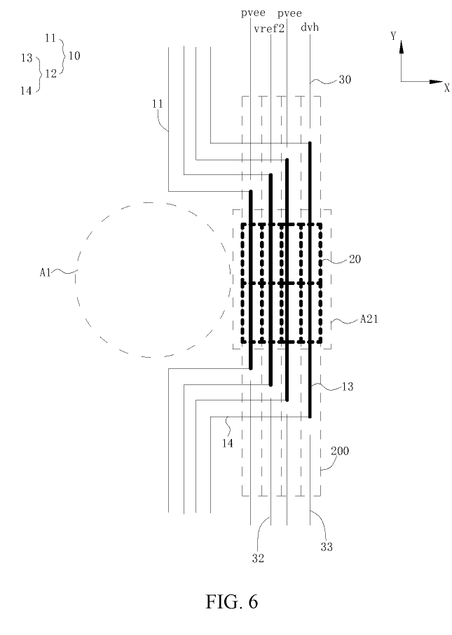

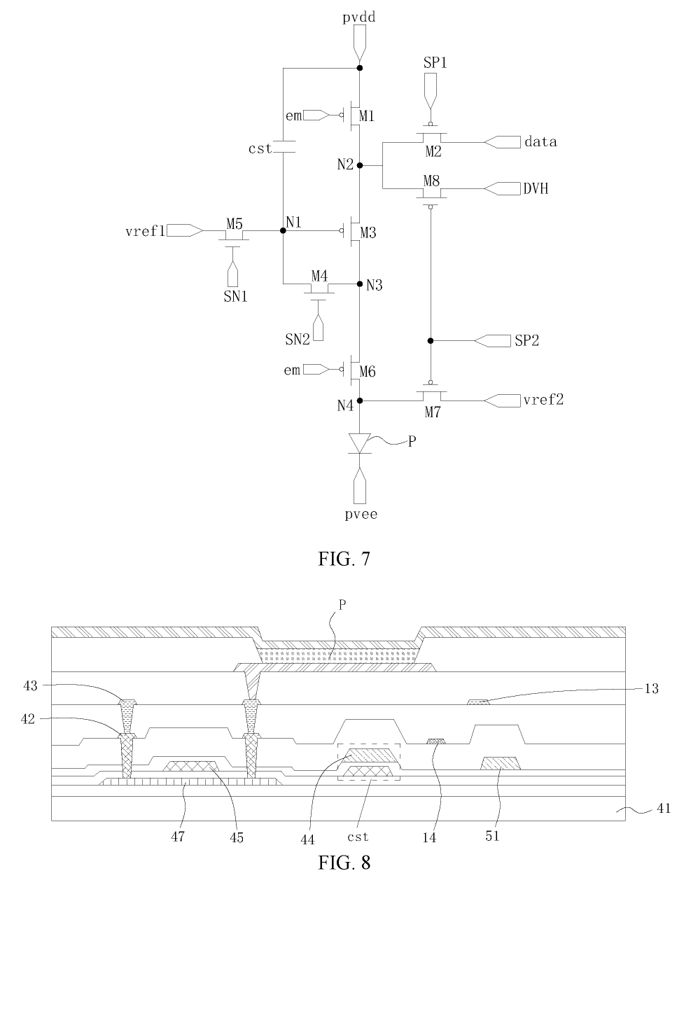

In other embodiments, referring to FIGS. 6 and 7, the multiple first line segments 30 configured to transmit the reset signals include a second-type trace 32 and a third-type trace 33, the second-type trace 32 is configured to transmit a second reset signal, and the third-type trace 33 is configured to transmit a third reset signal. The pixel circuit 20 includes a second reset transistor M7, a third reset transistor M8, and a driving transistor M3. A first electrode of the second reset transistor M7 is configured to receive the second reset signal vref2, and a second electrode of the second reset transistor M7 is electrically connected to the anode. A first electrode of the third reset transistor M8 is configured to receive the third reset signal dvh, and a second electrode of the third reset transistor M8 is electrically connected to a first electrode of the driving transistor M3.

The pixel circuit 20 in the embodiments of the present disclosure can have a circuit structure of 8T1C. In conjunction with the circuit diagrams, it can be seen that the first electrode of the second reset transistor M7 is configured to receive the second reset signal vref2, and the second electrode of the second reset transistor M7 is electrically connected to the anode. The second reset transistor M7 is configured to control whether the second reset signal vref2 is written to the anode. Thus, the second reset signal vref2 is a specific signal configured to reset the anode.

The first electrode of the third reset transistor M8 is configured to receive the third reset signal dvh, and the second electrode of the third reset transistor M8 is electrically connected to the second node N2, while the second node N2 is electrically connected to the first electrode of the driving transistor M3. On such basis, the third reset transistor M8 is configured to control whether the third reset signal dvh is written to a second node N2 and written to the first electrode of the driving transistor M3 through the second node N2. Thus, a bias state of the driving transistor M3 is adjusted, improving the hysteresis characteristics of the driving transistor M3.

In the embodiments of the present disclosure, the first line segment 30 configured to transmit the reset signal includes the second-type trace 32 and the third-type trace 33. The second-type trace 32 is configured to transmit the second reset signal vref2 and the third-type trace 33 is configured to transmit the third reset signal dvh, so that the second reset signal vref2 and the third reset signal dvh each correspond to vertical traces in a same layer as the second sub-segment 13. This facilitates the improvement of not only the transmission reliability of the second reset signal vref2 but also the transmission reliability of the third reset signal dvh, thereby improving the operational reliability of the pixel circuit 20.

It should be noted that, for the circuit structure of 8T1C mentioned in the embodiments of present disclosure, both the second reset signal vref2 and the third reset signal dvh can be configured to respectively correspond to vertical traces, while the first reset signal vref1 can be configured to correspond a horizontal trace disposed in a different layer from the second sub-segment 13 and does not correspond to a vertical trace. For the circuit structure of 7T1C mentioned in the above embodiments, since there is no third reset signal dvh, both the first reset signal vref1 and the second reset signal vref2 can be configured to respectively correspond to the vertical traces.

In summary, in combination with the above two implementation methods, it can be seen that the present disclosure can flexibly adjust the types of reset signals in the first line segments 30 according to the different types of pixel circuits 20 in the display panel, thereby improving the transmission reliability of specific types of reset signals. The above two implementation methods are merely two specific implementation method for two common circuit structures and the corresponding common layer layout methods for these two circuit structures, but the present disclosure is not limited thereto. For example, in other embodiments, the multiple first line segments 30 configured to transmit the reset signal can transmit a same signal, that is, the first line segments 30 are configured to transmit only the first power supply signal pvee and one type of reset signal.

In some embodiments, referring to FIGS. 4, 6, 8 and 9, the first detouring portion 12 further includes a third sub-segment 14 extending in the first direction X, one end of the third sub-segment 14 is connected to the first sub-segment 11, and another end of the third sub-segment 14 is connected to the second sub-segment 13. The display panel includes a substrate 41, a first conductor layer 42 disposed on a side of the substrate 41, and a second conductor layer 43 located on a side of the first conductor layer 42 away from the substrate 41. The third sub-segment 14 is located in the first conductor layer 42. The first sub-segment 11, the second sub-segment 13, and the first line segment 30 are all located in the second conductor layer 43.

The third sub-segment 14 is a trace structure of the first detouring portion 12 configured to connect the first sub-segment 11 with the second sub-segment 13. In a single first signal line 10, there are two third sub-segments 14 and two first sub-segments 11. The two third sub-segments 14 are respectively connected to the two first sub-segments 11, and the two third sub-segments 14 are respectively connected to two ends of the second sub-segment 13 in the second direction Y.

The third sub-segment 14 extends in the first direction X. Considering that if the first sub-segment 11 and the third sub-segment 14 are disposed in a same layer, it can easily lead to a risk that contact interference between the third sub-segment 14 and each of the first line segment 30 and both the second sub-segment 13 and the first sub-segment 11 in another first signal line 10. Therefore, in the embodiments of the present disclosure, the third sub-segment 14 is disposed in a different layer from the first sub-segment 11, the second sub-segment 13, and the first line segment 30, thereby reducing the risk of interference between the third sub-segment 14 and other trace structures and improving the reliability of each signal transmission.

Specifically, the display panel includes the substrate 41, the first conductor layer 42, and the second conductor layer 43 that are stacked in sequence. The substrate 41 serves as a functional layer playing a role of support. Both the first conductor layer 42 and the second conductor layer 43 include conductor materials. In addition to the first conductor layer 42 and the second conductor layer 43, the display panel can include other conductor layers. Other conductor layers can be provided between the substrate 41 and the first conductor layer 42, other conductor layers can be provided between the first conductor layer 42 and the second conductor layer 43, and a conductor layer can be provided on a side of the second conductor layer 43 away from the substrate 41, which are not limited in the present disclosure.

Further, in some embodiments of the present disclosure, the third sub-segment 14 is located in the first conductor layer 42, while the first sub-segment 11, the second sub-segment 13, and the first line segment 30 are all located in the second conductor layer 43. That is, the first sub-segment 11, the second sub-segment 13, and the first line segment 30 that have a same extending direction are disposed in a same layer, while the third sub-segment 14 extending a different direction from the extending direction of the first sub-segment 11, the second sub-segment 13, and the first line segment 30 each, is located in a different layer. In this way, the third sub-segment 14 can be connected to the first sub-segment 11 and the second sub-segment 13 through vias, which also reduces the risk of contact interference between the third sub-segment 14 and each of the first sub-segment 11, the second sub-segment 13, and the first line segment 30, thereby improving the reliability of each signal transmission.

In some embodiments, referring to FIGS. 4, 5, 8 and 10, the display panel further includes a first reset signal line 51 and a second reset signal line 52 each extending in the first direction X. The first reset signal line 51 is configured to transmit the first reset signal vref1 and is electrically connected to at least one of the first line segments 30. The second reset signal line 52 is configured to transmit the second reset signal vref2 and is electrically connected to at least one of the first line segments 30. The first reset signal line 51 and the second reset signal line 52 are located in a same layer and located on a side of the first conductor layer 42 facing towards the substrate 41.

The first reset signal line 51 is a horizontal trace configured to transmit the first reset signal vref1 and is electrically connected to at least one of the first line segments 30, so that the at least one of the first line segments 30 can transmit the first reset signal vref1. On such basis, the first line segments 30 respectively located at two sides of the second sub-segment 13 can be respectively connected to two first reset signal lines 51, so that even if these two first line segments 30 are not in direct contact with and not directly connected to each other, they can still be configured to transmit a same first reset signal vref1, meeting the transmission requirement of the first reset signal vref1. Further, since the first reset signal vref1 is transmitted on both a horizontal trace and a vertical trace, the trace structures each configured to transmit the first reset signal vref1 can form a mesh structure, thereby reducing the corresponding signal voltage drop and improving the reliability of signal transmission.

Similarly, the second reset signal line 52 is a horizontal trace configured to transmit the second reset signal vref2. The second reset signal line 52 is electrically connected to at least one of the first line segments 30, so that the at least one of the first line segments 30 can also transmit the second reset signal vref2. On such basis, the first line segments 30 located at two sides of the second sub-segment 13 can be connected to two second reset signal lines 52, respectively, so that even if these two first line segments 30 are not in direct contact with and not directly connected to each other, they can still be configured to transmit a same second reset signal vref2, meeting the transmission requirement of the second reset signal vref2. Additionally, since the second reset signal vref2 is transmitted on both a horizontal trace and a vertical trace, the trace structures each configured to transmit the second reset signal vref2 can form a mesh structure, thereby reducing the corresponding signal voltage drop and improving the reliability of signal transmission.

In the embodiments of the present disclosure, the first reset signal line 51 and the second reset signal line 52 each extending in the first direction X are provided, so as to meet the signal transmission requirement of the corresponding first line segment 30, while also facilitating to reducing the signal voltage drop of the first reset signal vref1 and the signal voltage drop of the second reset signal vref2, thereby improving the reliability of signal transmission. Further, considering that the first reset signal line 51 and the second reset signal line 52 have a same extending direction, it is chosen to dispose these two signal lines on the side of the first conductor layer 42 facing towards the substrate 41. In this way, the risk of contact interference between each the first reset signal line 51 and the second reset signal line 52 and other vertical traces is reduced. Additionally, these two signal lines are disposed in a same layer, facilitating to reducing the spatial occupation of other layers and facilitating the light and thin design of the display panel.

The specific layer form in the display panel is not limited in the embodiments of the present disclosure. As can be seen from the above contents, the pixel circuit 20 in the present disclosure can adopt a circuit structure of 7T1C. For example, the display panel provided by the embodiments of the present disclosure can be applicable to low temperature poly-silicon (LTPS) technology. Specifically, LTPS technology only includes LTPS-TFT, that is, the display panel includes only thin-film transistors using low-temperature poly-silicon as the active layer.

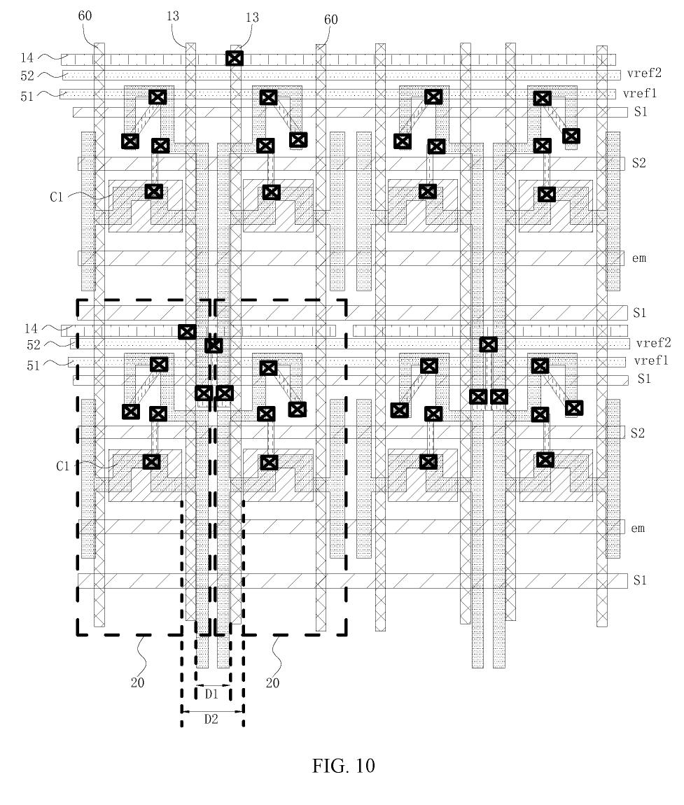

On such basis, as shown in FIGS. 8 and 10, the display panel can include a low-temperature poly-silicon active layer 47, a fourth conductor layer 45, a third conductor layer 44, a first conductor layer 42, and a second conductor layer 43 that are stacked in sequence towards a direction away from the substrate 41. The control terminals of the thin-film transistors and the lower electrode plate c1 of the storage capacitors cst are located in the fourth conductor layer 45, while an upper electrode plate of the storage capacitors cst, the first reset signal line 51, and the second reset signal line 52 are located in the third conductor layer 44.

In other embodiments, referring to FIGS. 6, 7, 9 and 11, the display panel includes a second reset signal line 52 and a third reset signal line 53 each extending in the first direction X. The second reset signal line 52 is configured to transmit the second reset signal vref2 and is electrically connected to at least one of the first line segments 30, and the third reset signal line 53 is configured to transmit the third reset signal dvh and is electrically connected to at least one of the first line segments 30. The second reset signal line 52 and the third reset signal line 53 are located in a same layer and located on the side of the first conductor layer 42 facing towards the substrate 41.

The second reset signal line 52 is a horizontal trace configured to transmit the second reset signal vref2 and is electrically connected to at least one of the first line segments 30, so that the at least one first line segment 30 can transmit the second reset signal vref2. On such basis, the first line segments 30 respectively located at two sides of the second sub-segment 13 can be respectively connected to two second reset signal lines 52, so that even if these two first line segments 30 are not in direct contact with and not directly connected to each other, they can still be configured to transmit a same second reset signal vref2, meeting the transmission requirement of the second reset signal vref2. Additionally, since the second reset signal vref2 is transmitted on both a horizontal trace and a vertical trace, the trace structures configured to transmit the second reset signal vref2 can form a mesh structure, thereby reducing the corresponding signal voltage drop and improving the reliability of signal transmission.

Similarly, the third reset signal line 53 is a horizontal trace configured to transmit the third reset signal dvh and is electrically connected to at least one of the first line segments 30, so that the at least one first line segment 30 can transmit the third reset signal dvh. On such basis, the first line segments 30 respectively located at two sides of the second sub-segment 13 can be respectively connected to the two third reset signal lines 53, so that even if the two first line segments 30 are not in direct contact with and not directly connected to each other, they can still be configured to transmit a same third reset signal dvh, meeting the transmission requirement of the third reset signal dvh. Additionally, since the third reset signal dvh is transmitted on both a horizontal trace and a vertical trace, the trace structures configured to transmit the third reset signal dvh can form a mesh structure, thereby reducing the corresponding signal voltage drop and improving the reliability of signal transmission.

In the embodiments of the present disclosure, the second reset signal line 52 and the third reset signal line 53 each extending in the first direction X are provided so as to meet the signal transmission requirement of the corresponding first line segment 30, while also facilitating to reducing the signal voltage drop of the second reset signal vref2 and the signal voltage drop of the third reset signal vref3, thereby improving the reliability of signal transmission. Further, considering that the second reset signal line 52 and the third reset signal line 53 have a same extending direction, it is chosen to dispose these two signal lines on the side of the first conductor layer 42 facing towards the substrate 41, thereby reducing the risk of contact interference between each of the second reset signal line 52 and the third reset signal line 53 and other longitudinal traces. Additionally, these two signal lines are disposed in a same layer, facilitating to reducing the spatial occupation of other layers and facilitating the light and thin design of the display panel.

The specific form of layers in the display panel is not limited in the embodiments of the present disclosure. As can be seen from the above contents, the pixel circuit 20 in the present disclosure can adopt a circuit structure of 8T1C. For example, the display panel provided in the embodiments of the present disclosure can be applicable to low temperature polysilicon oxide (LTPO) technology. Specifically, LTPO technology is a hybrid of LTPS-TFT and indium gallium zinc oxide (IGZO)-TFT, that is, the display panel includes both thin-film transistors using low-temperature poly-silicon as the active layer and transistors using metal oxides as the active layer.

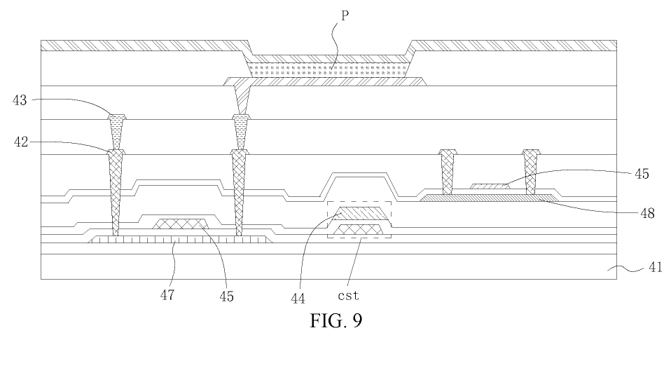

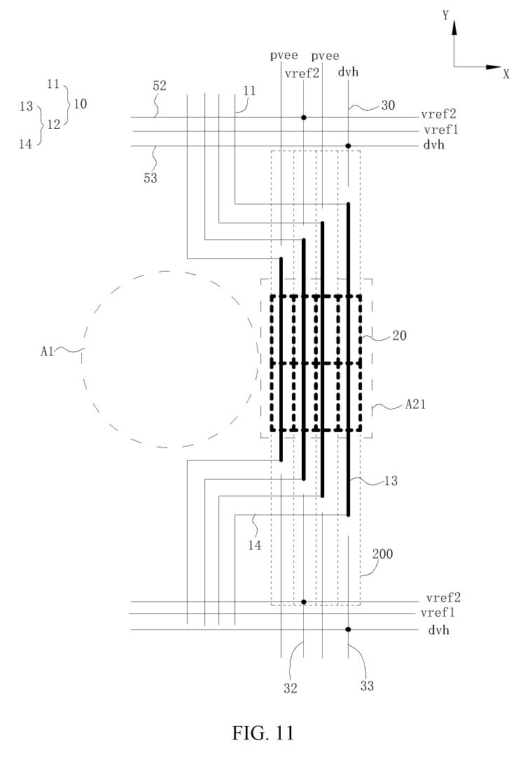

On this basis, as shown in FIGS. 9 and 11, the display panel can include a low-temperature poly-silicon active layer 47, a fourth conductor layer 45, a third conductor layer 44, a metal oxide active layer 48, a fifth conductor layer 46, a first conductor layer 42, and a second conductor layer 43 that are stacked in sequence along a direction away from the substrate 41. The control terminals of at least part of the thin-film transistors and the lower electrode c1 of the storage capacitor cst are located in the fourth conductor layer 45, and the upper electrode of the storage capacitor cst, the second reset signal line 52, and the third reset signal line 53 are located in the third conductor layer 44. The control terminals of other thin-film transistors are located in the fifth conductor layer 46. The first reset signal vref1 corresponds only to the horizontal trace located in the third conductor layer 44 and does not correspond to the vertical trace in the second conductor layer 43.

In some embodiments, as shown in FIG. 10, the pixel circuit 20 includes a driving transistor M3. A distance between adjacent second sub-segments 13 in the first direction X is D1, and a distance D2 between two driving transistors M3 in two adjacent pixel circuits 20 in the first direction X is D2, where D2 > D1.

In combination with the figures, it can be seen that the lower electrode c1 of the storage capacitor cst is also used as the control terminal of the driving transistor M3. On such basis, the distance D2 can represent a distance between two lower electrode plates c1 of adjacent pixel circuits 20 in the first direction X, while the distance D1 can represent a distance between two second sub-segments 13 correspond to adjacent pixel circuits 20 in the first direction X.

In the embodiments of the present disclosure, D2 > D1 indicates that projections of adjacent second sub-segments 13 in the thickness direction Z of the display panel each are located between projections of adjacent lower electrodes c1. Such design allows the second sub-segment 13 to correspond to an edge region of the pixel circuit 20 in the first direction X, thereby reducing an overlapping area between the second sub-segments 13 and the structure in a central region of the pixel circuit 20 (such as the driving transistor M3), thereby reducing its adverse effects on the operation of the pixel circuit 20 and improving the light-emitting reliability of the display panel.

It should be noted that the solution provided in the embodiments of the present disclosure is applicable to the case where the adjacent pixel circuits 20 shown in FIG. 9 adopt a mirror design, that is, the pixel circuits 20 adjacent in the first direction X are symmetrical relative to a virtual straight line parallel to the second direction Y. Specifically, a virtual straight line is provided between the pixel circuits 20 adjacent to each other in the first direction X, and a distance between the lower electrode plate c1 of the storage capacitor cst of one of these adjacent pixel circuits 20 and the virtual straight line in the first direction X is equal to a distance between the lower electrode plate c1 of the storage capacitor cst of the other pixel circuit of these adjacent pixel circuits and the virtual straight line in the first direction X. On such basis, adjacent second sub-segments 13 respectively corresponding to the adjacent pixel circuits 20 are respectively provided at two sides of the virtual straight line. Further optionally, the adjacent second sub-segments 13 are equidistant from the virtual straight line in the first direction X.

In some embodiments, the pixel circuit 20 includes a driving transistor M3, and the adjacent second sub-segments 13 are located at a same side of the driving transistor in the first direction X, and are equidistant from the corresponding driving transistor M3 in the first direction X.

It should be noted that the “being located at a same side of the driving transistor” as mentioned in the embodiments of the present disclosure refers to being located at a same side as the control terminal of the driving transistor M3 in the first direction X, that is, being located at a same side of the lower electrode plate c1 of the storage capacitor cst in the first direction X.

In the embodiments of the present disclosure, the second sub-segment 13 does not overlap the driving transistor M3 but is located at a side of the driving transistor. Such design allows the second sub-segment 13 to correspond to the edge region of the pixel circuit 20 in the first direction X, thereby reducing the overlapping area between the second sub-segments 13 and the structure of the pixel circuit 20 in the central region (such as the driving transistor M3), alleviating its adverse effects on the operation of the pixel circuit 20, and improving the light-emitting reliability of the display panel.

Further, adjacent second sub-segments 13 are located at a same side of the corresponding driving transistor and are equidistant from the corresponding driving transistor M3 in the first direction X. That is, different second sub-segments 13 correspond to regions of the corresponding pixel circuits 20, respectively, which facilitates to improving positional reliability of multiple second sub-segments 13 relative to the pixel circuit 20 and reduces the design and fabrication difficulty of the second sub-segments 13.

It should be noted that the solution provided by the embodiments of the present disclosure is applicable to situations where adjacent pixel circuits 20 has a same projection morphology in the thickness direction Z of the display panel. On such basis, the solution provided by the embodiments of the present disclosure facilitates to further improving the structural similarity of the display panel at different pixel circuits 20s, thereby further reducing the design and fabrication difficulty of the display panel.

In some embodiments, as shown in FIG. 10, the display panel includes a second signal line 60 extending in the second direction Y, located in the second region A2, and located at either side of the first region A1 in the first direction X. The pixel circuit 20 includes a storage capacitor cst. The projection of the second sub-segment 13 in the thickness direction Z of the display panel and a projection of the second signal line 60 in the thickness direction Z of the display panel are arranged at two opposite sides of the storage capacitor cst in the first direction X, respectively.

Similar to the first signal line 10, the second signal line 60 is also located in the second region A2 and extends in the second direction Y. However, different from the first signal line 10, the second signal line 60 is entirely located at either side of the first region A1 in the first direction X, that is, an extending path of the second signal line 60 does not need to be designed to avoid the first region A1. The first signal line 10 and the second signal line 60 can be configured to transmit a same signal or can transmit different signals, respectively, which is not limited in the embodiments of the present disclosure. Optionally, both the first signal line 10 and the second signal line 60 can be configured to transmit data signals.

For multiple second signal lines 60, the multiple second signal lines 60 can be disposed at different sides of the first region A1 in the first direction X, respectively, while at least one of the second signal lines 60 can extend through the first sub-region A21, that is, the second sub-segment 13 and at least one of the second signal lines 60 can overlap a same circuit column 200. Further, with a same extending direction, the second signal line 60 and the second sub-segment 13 can be disposed in a same layer. On such basis, to reduce the effect of the second signal line 60 to the second sub-segment 13 and to meet the layout requirements of the second signal line 60 and the second sub-segment 13, the embodiments of the present disclosure also adjusts the positions of the second signal line 60 and the second sub-segment 13 relative to the pixel circuit 20.

Specifically, the pixel circuit 20 includes a storage capacitor cst, and projections of the second sub-segment 13 and the second signal line 60 are respectively located at two opposite sides of a projection of the storage capacitor cst in the first direction X. The storage capacitor cst includes a lower electrode plate c1 and an upper electrode plate located on a side of the lower electrode plate c1 away from the substrate 41. The “projection of the storage capacitor cst” referred to in the present disclosure refers to a projection of the lower electrode plate c1 in the thickness direction Z of the display panel.

In the embodiments of the present disclosure, the projections of the second sub-segment 13 and the second signal line 60 are disposed at two opposite sides of the projection of the storage capacitor cst, respectively, so that a certain spacing in the first direction X is provided between the second sub-segment 13 and the second signal line 60 that overlap a single circuit column 200, thereby reducing the risk of contact interference between the second sub-segment 13 and the second signal line 60, and reduces the risk of signal interference between the second sub-segment 13 and the second signal line 60, thereby improving the operational reliability of the display panel.

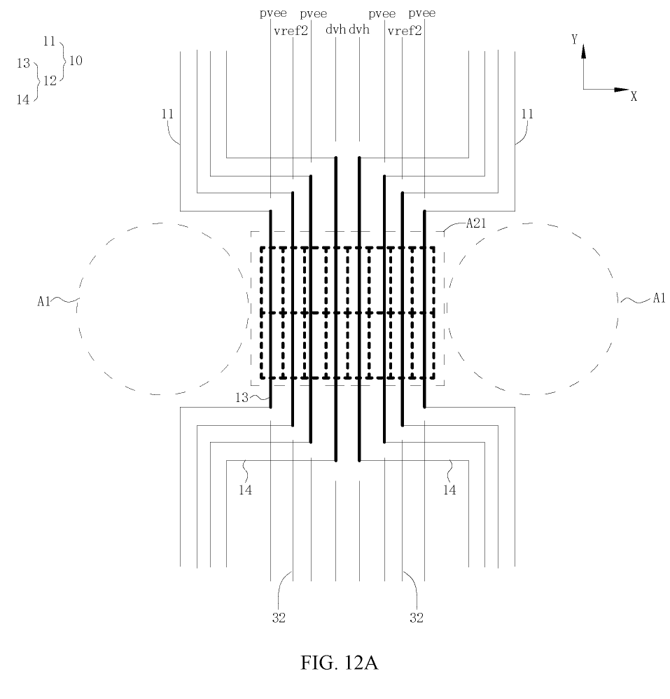

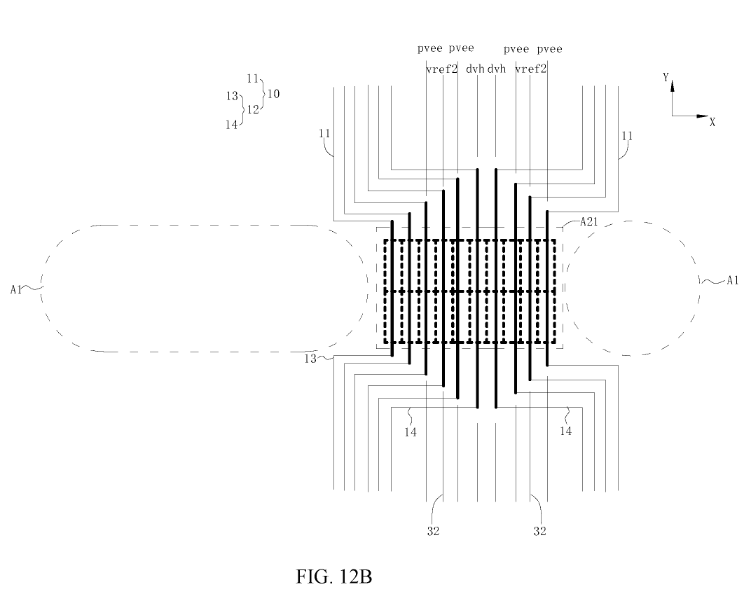

In some embodiments, referring to FIGS. 12A and 12B, the number of first regions A1 is greater than or equal to two, and multiple first regions A1 are spaced apart from each other in the first direction X, and the first sub-region A21 is provided between adjacent first regions A1.

There are multiple first regions A1, and dimensions and shapes of different first regions A1 can be the same or different from each other. FIG. 12A illustrates a case where two first regions A1 have a same shape of a circle, while FIG. 12B illustrates a case where one first region A1 is elliptic and the other first region A1 is circular.

In the display apparatus, photosensitive components are disposed on the back of the display panel at positions corresponding to the multiple first regions A1. Since there can be various dimension relationships between a single photosensitive component and a single first region A1, multiple first regions A1 can correspond to a same photosensitive component, or the multiple first regions A1 can correspond to different photosensitive components, respectively.

Multiple first regions A1 are spaced apart from each other in the first direction X. In general, a region between adjacent first regions A1 in the first direction X often has a small size, and the size of this region often fails to meet the requirements of conventional line detouring design solution. Especially for the elliptic first region A1 shown in FIG. 12B, the ellipse configuration requires more first signal lines 10 to detour round the first region A1, thereby so more detour line structures need to be integrated between adjacent first regions A1, which increases the difficulty in the design of the detour line.

In view of this, the present disclosure adjusts the wiring manner in the region between adjacent first regions A1, such that at least two adjacent second sub-segments 13 overlap adjacent circuit columns 200, respectively, thereby minimizing the spacing between adjacent second sub-segments 13 and enabling more second sub-segments 13 to be disposed between adjacent first regions A1 to meet actual line detouring requirements. Further, on the premise that the line detouring requirements are met, a dimension of part of the space between adjacent first regions A1 can be selectively minimized to increase an area of other display regions in the display panel, thereby improving display performance.

It should be noted that in the embodiments of the present disclosure, the detour line structures corresponding to all first regions A1 can be disposed only in the first sub-region A21 between adjacent first regions A1, or at least one of the detour line structures can be disposed in the first sub-region A21 between adjacent first regions A1 and at least one of the detour line structures can be disposed in a region at a periphery of the first region A1 and between first regions A1 not adjacent to each other, which is not limited in the embodiments of the present disclosure.

In addition, the present disclosure presents only a case where the first sub-region A21 is located between adjacent first regions A1. However, in other embodiments, the first sub-region A21 can be located at a side of the first region A1 in the first direction X and located in the region between first regions A1 not adjacent to each other as long as at least two adjacent second sub-segments 13 overlap adjacent circuit columns 200, respectively.

In some embodiments, the display panel includes light-emitting units P, and the pixel circuits 20 in the first sub-region A21 are electrically connected to the light-emitting units P, respectively, and/or the light-emitting units P in the first region A1 are electrically connected to the pixel circuits 20 located in the first sub-region A21, respectively.

As can be seen from the drawings and the above contents, the first sub-region A21 is provided with both the second sub-segment 13 and the pixel circuit 20. For the pixel circuits 20, the pixel circuits 20 in the first sub-region A21 can be configured to control the light-emitting units P. On such basis, the pixel circuits 20 in the first sub-region A21 and the corresponding light-emitting units P can have various positional relationships.

Specifically, in one case, at least one of the pixel circuits 20 in the first sub-region A21 can be configured to control at least one light-emitting unit P in the first sub-region A21. In this case, the projection of the pixel circuit 20 in the first sub-region A21 in the thickness direction Z of the display panel overlaps the projection of the corresponding light-emitting unit P in the thickness direction Z of the display panel. In another case, light-emitting units P are provided in the first region A1, and at least one of the pixel circuits 20 in the first sub-region A21 is configured to control at least one light-emitting unit P in the first region A1. In this case, the projection of the pixel circuit 20 in the first sub-region A21 in the thickness direction Z of the display panel is staggered with the projection of the corresponding light-emitting unit P in the thickness direction Z of the display panel.

In the embodiments of the present disclosure, the pixel circuit 20 in the first sub-region A21 can be configured to control the light-emitting unit P located in the first sub-region A21 to achieve a light-emitting function, or can be configured to control the light-emitting unit P located in the first region A1 to achieve a light-emitting function. On such basis, a relative positional relationship between the pixel circuit 20 in the first sub-region A21 and the corresponding light-emitting unit P can be flexibly adjusted to meet different display requirements.

Of course, in another embodiment, the pixel circuit 20 in the first sub-region A21 is a dummy pixel circuit 20.

Different from the above implementation, the pixel circuit 20 in the first sub-region A21 is not configured to control the light-emitting unit P. The dummy pixel circuit 20 in the first sub-region A21 can has have a same or similar circuit structure, function, and performance to the effective pixel circuits 20 in other regions, thereby matching the performance of the effective pixel circuits 20 and improving the stability and consistency of the display panel.

It should be noted that although the dummy pixel circuit 20 does not control the light-emitting unit P, to improve circuit consistency, the signal traces configured to transmit the data signal data and the signal traces configured to transmit the second power supply signal pvdd still need to pass through the dummy pixel circuit 20, that is, through the first sub-region A21. On such basis, the second sub-segment 13 can extend through the pixel circuits 20 in the first sub-region A21, thereby ensuring that the trace layouts at these pixel circuits 20 are identical to the trace layouts at the pixel circuits 20 in other regions, thereby improving the consistency of the display panel.

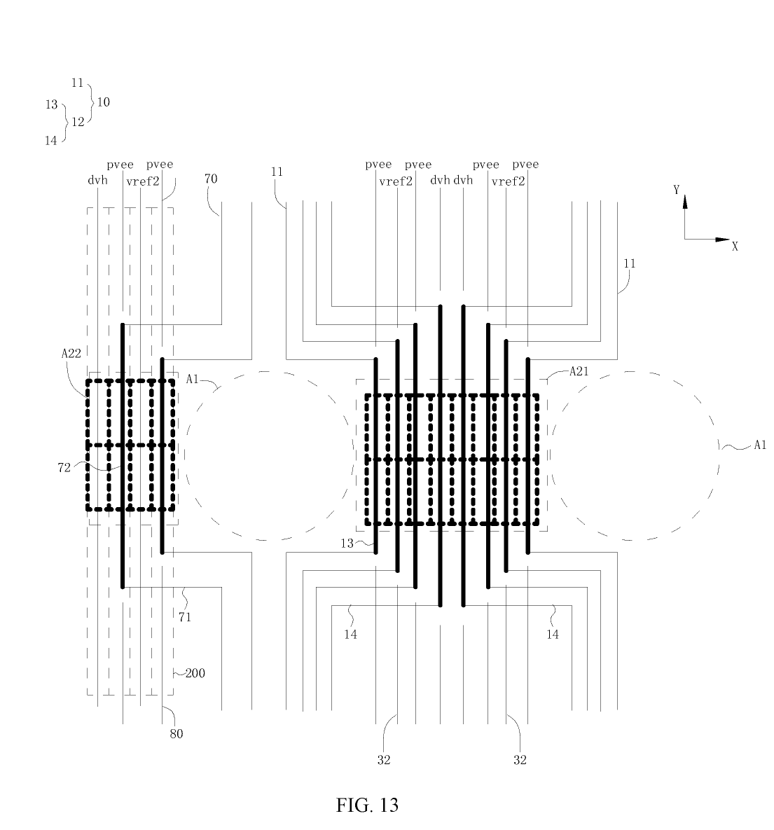

In some embodiments, referring to FIGS. 13-15, the second region A2 includes a second sub-region A22 located at a side of the first region A1 in the first direction X, and the first sub-region A21 does not overlap the second sub-region A22. The display panel further includes a third signal line 70 disposed in the second region A2. The third signal line 70 extends in the second direction Y and includes a second detouring portion 71, and the second detouring portion 71 includes a fourth sub-segment 72 extending in the second direction Y and located in the second sub-region A22. In the thickness direction Z of the display panel, adjacent fourth sub-segments 72 are offset from circuit columns 200, respectively, or adjacent fourth sub-segments 72 overlap adjacent circuit columns 200, respectively.

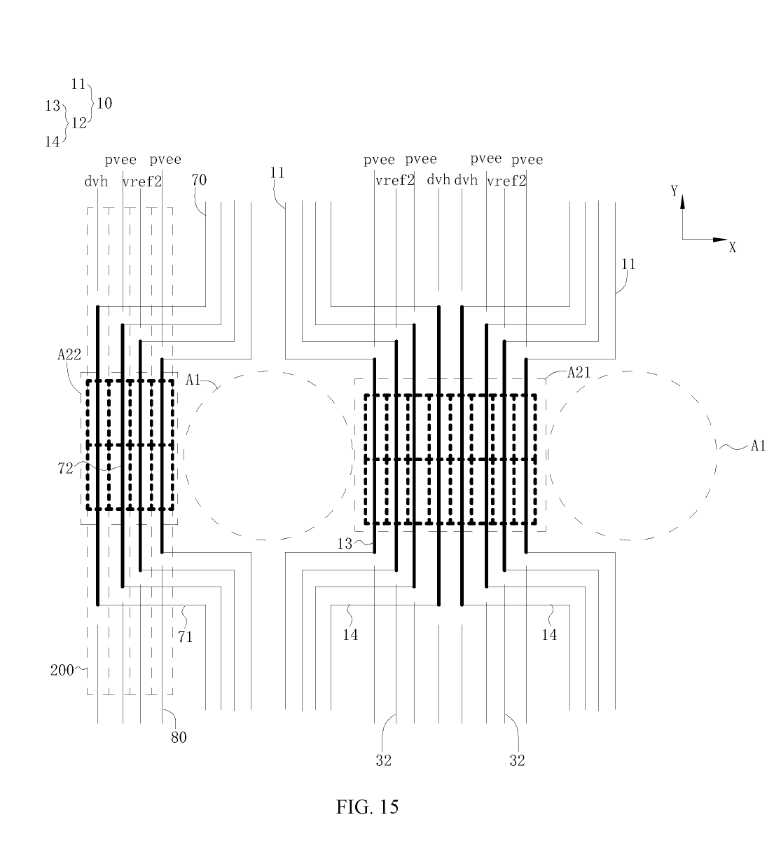

Similar to the first sub-region A21, the second sub-region A22 is also located at the periphery of a hole region and needs to be provided with a detour line structure. The first sub-region A21 and the second sub-region A22 are both located at a side of the first region A1 in the first direction X. The first sub-region A21 and the second sub-region A22 can have various positional relationships. Taking both the first sub-region A21 and the second sub-region A22 are provided at the periphery of a single first region A1 as an example, the first sub-region A21 and the second sub-region A22 can be located at opposite sides of the first region A1, respectively, or the first sub-region A21 can be located between the first region A1 and the second sub-region A22, or the second sub-region A22 can be located between the first region A1 and the first sub-region A21. Further, as shown in FIGS. 13 and 15, if the display panel has multiple first regions A1, the first sub-region A21 can be located between adjacent first regions A1, while the second sub-region A22 can be located on in a region at the periphery of the first region A1 and between the first regions A1 not adjacent to each other.

Similar to the first signal line 10, a primary structure of the third signal line 70 also needs to extend in the second direction Y, and the third signal line 70 needs to detour round the first region A1. However, the difference is that the first detouring portion 12 of the first signal line 10 is located in the first sub-region A21 while the second detouring portion 71 of the third signal line 70 is located in the second sub-region A22. The second detouring portion 71 includes a fourth sub-segment 72 extending in the second direction Y and located in the second sub-region A22. Optionally, the fourth sub-segment 72 is located in a same layer as the second sub-segment 13, that is, the fourth sub-segment 72 and the second sub-segment 13 are made of a same material and fabricated simultaneously in a same process.

In the embodiments of present disclosure, the display panel includes the first sub-region A21 and the second sub-region A22 that are configured to accommodate detour line structures. In conjunction with the above contents, it can be known that at least two adjacent second sub-segments 13 overlap adjacent circuit columns 200 correspondingly in the first sub-region A21, respectively, thereby increasing the distribution density of the second sub-segments 13 in the first sub-region A21 and allowing that more detour line structures can be provided in the first sub-region A21.

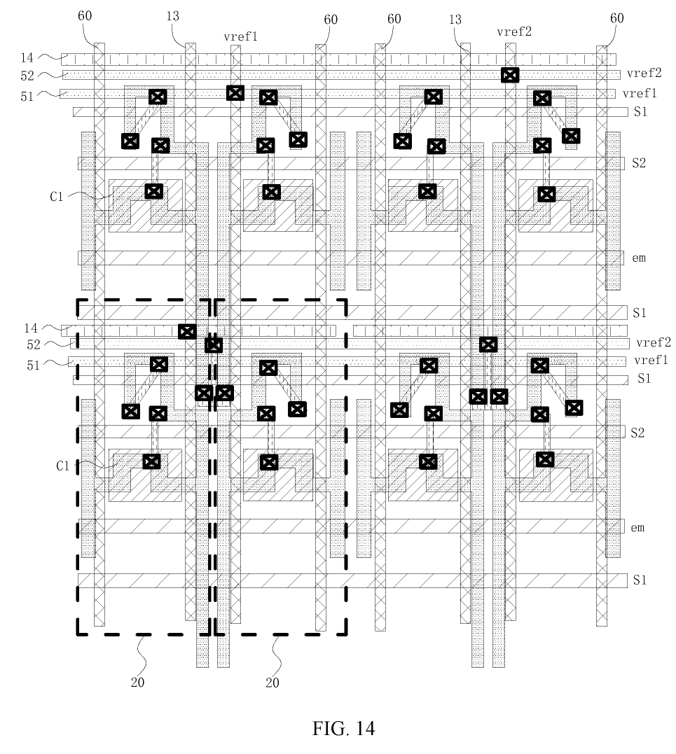

On such basis, considering that more detour line structures can be provided in the first sub-region A21, less detour line structures can be provided in the second sub-region A22. As shown in FIGS. 13 and 14, it can be chosen to set two adjacent fourth sub-segments 72 to overlap two circuit columns 200 that are spaced apart from each other. Of course, in other cases, with respect to cases such as excessive detour line structures or too small area of the second sub-region A22, as shown in FIG. 15, it can be chosen to set adjacent fourth sub-segments 72 to respectively overlap adjacent circuit columns 200, thereby meeting the layout requirements for different cases and offering strong flexibility and practicality.

In some embodiments, as shown in FIGS. 13 and 15, the display panel includes a second line segment 80 located in a same layer as and insulated from the fourth sub-segment 72. The second line segment 80 extends in the second direction Y and is positioned between adjacent fourth sub-segments 72. In the thickness direction Z of the display panel, the second line segment 80 and the fourth sub-segment 72 respectively overlap different circuit columns 200.

In the embodiments of the present disclosure, with respect to a case where there is a large spacing between adjacent fourth sub-segments 72 in the second sub-region A22, the embodiments of the present disclosure provide the second line segment 80 in the display panel. Different from the first line segment 30, the second line segment 80 can extend through the second sub-region A22. In this way, both the second line segment 80 and the fourth sub-segment 72 can be provided in the second sub-region A22. Further, the second line segment 80 and the fourth sub-segment 72 respectively overlap different circuit columns 200, so that the second line segment 80 and the fourth sub-segment 72 can be spaced apart from each other in the first direction X, thereby reducing the risk of contact interference between the second line segment 80 and the fourth sub-segment 72 to dispose the second line segment 80 and the fourth sub-segment 72 in a same layer. Optionally, in the second sub-region A22, multiple second line segments 80 and multiple fourth sub-segments 72 are alternately distributed in the first direction X.

In some optional embodiments, the display panel includes third line segments, two third line segments are respectively disposed at two sides of the fourth sub-segment 72 in the second direction Y and overlap a same circuit column 200. Further optionally, the second line segment 80 and the third line segment overlap different circuit columns 200, respectively.

The specific type of the signal transmitted by the second line segment 80 is not limited in the embodiments of the present disclosure. In some embodiments, at least one of the second line segments 80 is configured to transmit the first power supply signal pvee, and/or at least one of the second line segments 80 is configured to transmit the reset signal.

In the embodiments of the present disclosure, at least one of the vertical trace configured to transmit the first power supply signal pvee or the vertical trace configured to transmit the reset signal can extend through the second sub-region A22, thereby facilitating to improving the reliability of the corresponding signal transmission. Further optionally, when the display panel includes both the second line segment 80 and the third line segment, one of the second line segment 80 and the third line segment is configured to transmit the first power supply signal pvee, and the other one of the second line segment 80 and the third line segment is configured to transmit the reset signal.

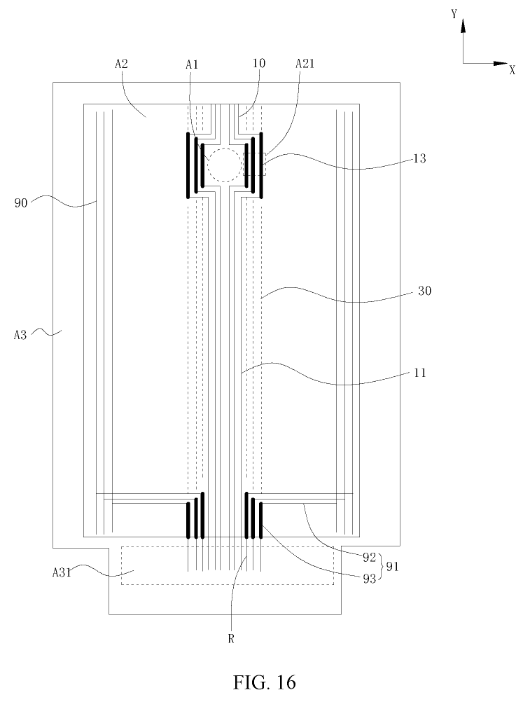

In some embodiments, referring to FIGS. 2 and 16, the display panel includes a third region A3 surrounding the second region A2, and the region A3 includes a fan-out region A31 located at a side of the second region A2 in the second direction Y. The display panel further includes a fourth signal line 90, and the fourth signal line 90 is located at either side of the first region A1 in the first direction X and electrically connected to a fan-out line R in the fan-out region A31 through a third detouring portion 91. The third detouring portion 91 is located in the second region A2 and includes a fifth sub-segment 92 extending in the first direction X and a sixth sub-segment 93 extending in the second direction Y. FIG. 16 illustrates six sixth sub-segments 93, of which three left sixth sub-segments 93 are adjacent to each other and three right sixth sub-segments 93 are adjacent to each other.

The third region A3 is the non-display region of the display panel at its edge bezel. The third region A3 and the second region A2 can have various kinds of morphology, and the morphology of the third region A3 and the morphology of the second region A2 can be correspondingly matched to each other. For example, an outer contour of the second region A2 can be circular, and the third region A3 can be a circular ring structure. Alternatively, the outer contour of the second region A2 can be square, and the third region A3 can be a square ring structure.

With reference to the accompanying drawings, it can be seen that the fan-out region A31 is a local region of the third region A3 located at a lower bezel of the display panel. The dimension of the fan-out region A31 in the first direction X is usually smaller than the dimension of the second region A2 in the first direction X, and the first region A1 and the fan-out region A31 can overlap in the second direction Y. The fourth signal line 90 is a vertical trace in the display panel that is configured to transmit a specific signal. The fourth signal line 90 is a signal sub-line located at either side of the first region A1 in the first direction X. The fourth signal line 90 can transmit a same type of signal as the first signal line 10, or the fourth signal line 90 and the first signal line 10 can transmit different types of signals.

In the embodiment of the present disclosure, the fan-out region A31 is provided with the fan-out line R. The third detouring portion 91 is provided and includes the fifth sub-segment 92 extending in the first direction X and the sixth sub-segment 93 extending in the second direction Y, so that the third detouring portion 91 can have a certain extending dimension in the first direction X and also have a certain extending dimension in the second direction Y. On such basis, the fan-out line R is tilted, and with only the third detouring portion 91, the fourth signal line 90 and the trace structure in the fan-out region A31 are electrically connected to each other. Further, the third detouring portion 91 is located in the second region A2 rather than in the third region A3, which facilitates to reducing the dimension of the third region A3, saves the wiring space at the lower bezel of the display panel, and facilitates to realizing a narrow bezel.

It should be noted that FIG. 16 illustrates that the fan-out line R is connected to the sixth sub-segment 93. The fan-out line R and the sixth sub-segment 93 are located in different layers, and to better distinguish these two trace structures, FIG. 16 illustrates the fan-out line R with a bold line and the sixth sub-segment 93 with a non-bold line.

Additionally, in addition to the fourth signal line 90 being electrically connected to the fan-out line R through the third detouring portion 91, the first signal line 10 can also be electrically connected to the trace structure in the fan-out region A31 through the third detouring portion 91. Alternatively, if the first signal line 10 and the corresponding fan-out line R correspondingly electrically connected to the first signal line 10 can be aligned with each other in the second direction Y, they can be directly connected to each other without through the third detouring portion 91.

In some embodiments, in the thickness direction Z of the display panel, at least two adjacent sixth sub-segments 93 overlap the adjacent circuit columns 200 respectively.

In the embodiments of the present disclosure, in addition to adjusting the detour line structure located at the periphery of the first region A1, the detour line structure located in the second region A2 close to the fan-out region A31 can also be adjusted and designed, and at least two adjacent sixth sub-segments 93 overlap the adjacent circuit columns 200, respectively, thereby facilitating to minimizing the spacing between adjacent sixth sub-segments 93, increasing the distribution density of multiple sixth sub-segments 93 in the unit area, and meeting the trace layout requirement of the display panel.

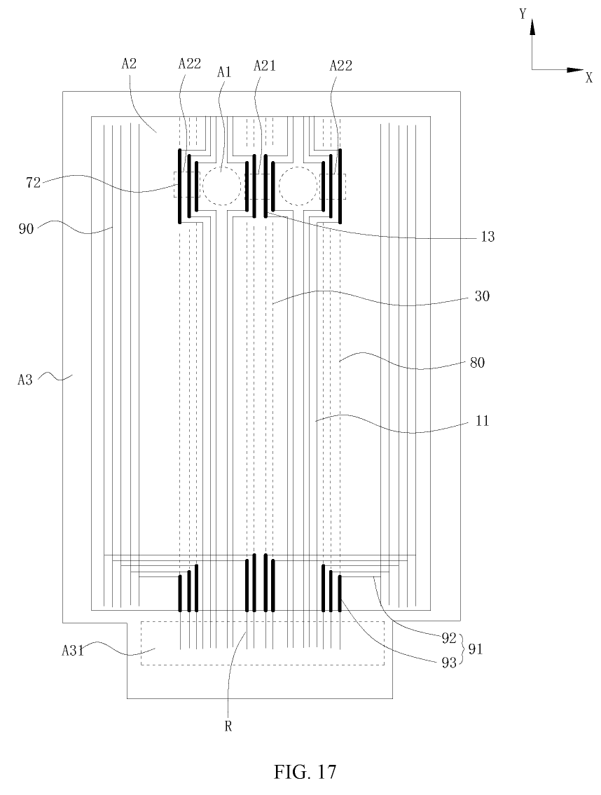

In some embodiments, referring to FIGS. 16-19, the display panel includes a first line segment 30 located in a same layer as and insulated from the second sub-segment 13 and the sixth sub-segment 93. The first line segment 30 extends in the second direction Y, and the first line segments 30 are located at two sides of the second sub-segment 13, respectively. The first line segment 30 is located at a side of the sixth sub-segment 93 facing towards the second sub-segment 13, and the first line segment 30 and the sixth sub-segment 93 overlap a same circuit column 200 in the thickness direction Z of the display panel. In FIGS. 16 and 17, to facilitate distinguishing the first line segment 30 from the fan-out line R, the first line segment 30 is illustrated with a dashed straight line.

It should be noted that FIGS. 16-19 illustrate only at least one of the sixth sub-segments 93 corresponding to the first line segment 30 and fail to illustrate the sixth sub-segment 93 corresponding to the first sub-segment 11 and the sixth sub-segments 93 corresponding to other trace structures. Additionally, taking the first signal line 10 being a data line configured to transmit the data signal data as an example, FIGS. 16-18 illustrate only at least one of the data lines including the second sub-segment 13 and fail to illustrate other data lines.

In the embodiments of the present disclosure, the third detouring portion 91 includes the sixth sub-segment 93, and the sixth sub-segment 93 can be disposed in a same layer as the first line segment 30 and have a same extending direction as the first line segment 30. On such basis, to reduce the interference between the sixth sub-segment 93 and the first line segment 30, some embodiments of the present disclosure provide the first line segment 30 at the side of the sixth sub-segment 93 facing towards the second sub-segment 13, that is, at least one of the first line segment 30 does not extend to the edge of the second region A2 close to the fan-out region A31, thereby forming a spacing between the sixth sub-segment 93 and the first line segment 30 to meet their insulation requirements.

It should be noted that FIGS. 16-19 illustrate various different wiring manners in different types of display panels under the premise that at least two adjacent sixth sub-segment 93 respectively overlap adjacent circuit columns 200. Specifically, FIG. 16 illustrates that the display panel includes only one first region A1, and the first sub-region A21 is located at least one side of the first region A1 in the first direction X. In this case, at least one of the sixth sub-segments 93 and the first line segment 30 can overlap a same circuit column 200.

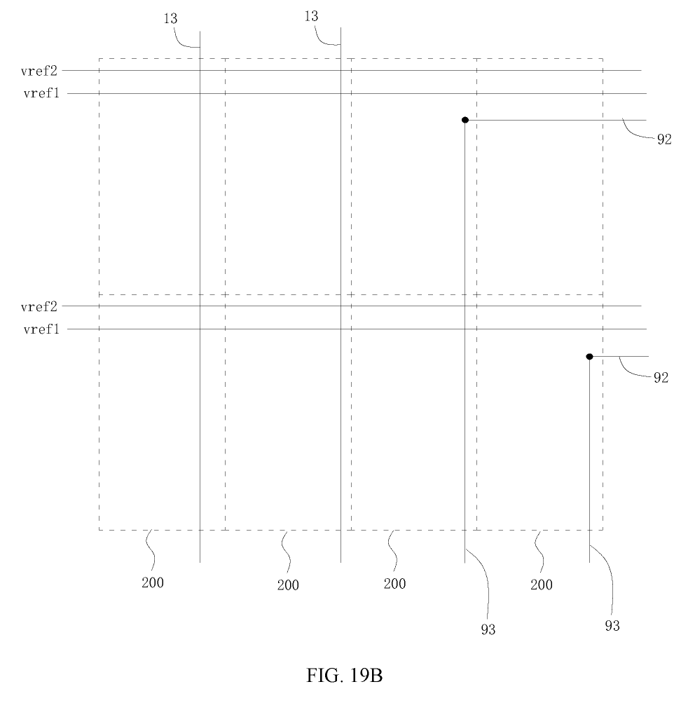

FIGS. 17 and 19 both illustrate a case where the display panel includes multiple first regions A1, the first sub-region A21 is located between adjacent first regions A1, and the second sub-region A22 are located at a same side of all first regions A1. The first line segment 30 and the second line segment 80 are both indicated by dashed straight lines. In this case, all first line segments 30 can be configured to transmit the first power supply signal pvee, or at least one of the first line segments 30 can be configured to transmit the first power supply signal pvee and other first line segments are configured to transmit the reset signal.

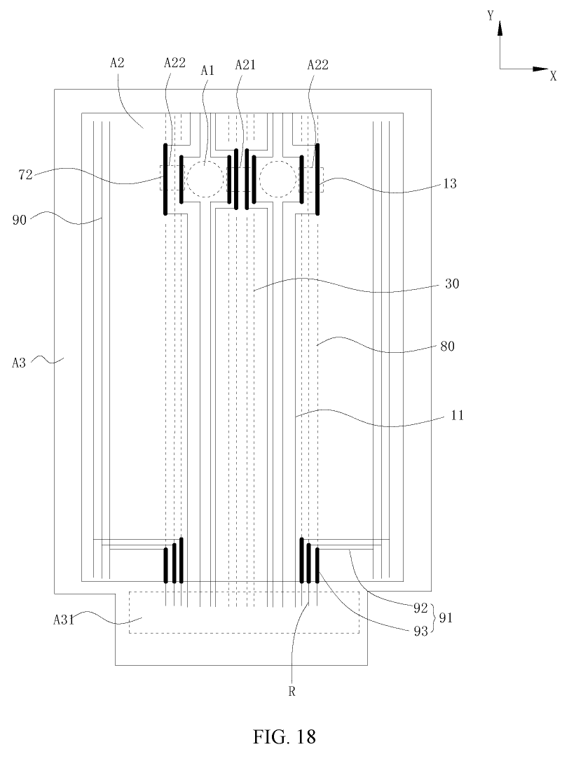

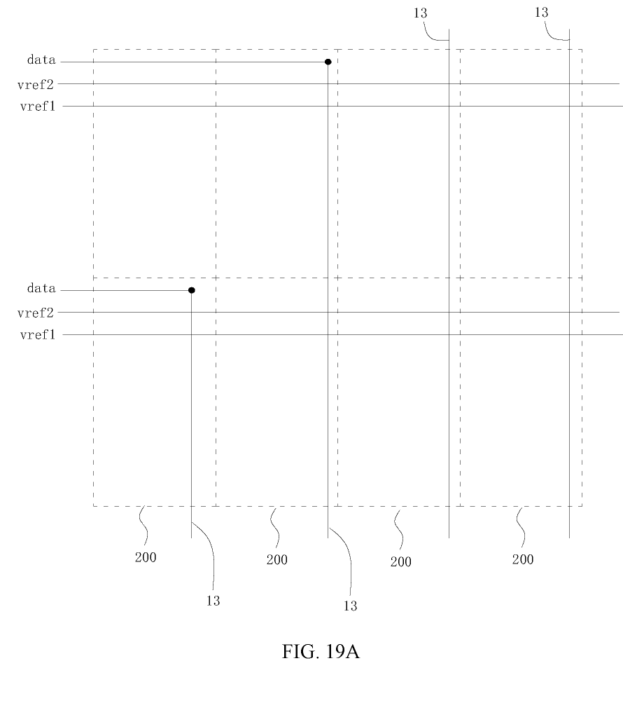

Further, as shown in FIG. 17, at least one of the sixth sub-segments 93 and the first line segment 30 overlap a same circuit column 200, and at least one of the sixth sub-segments 93 and the second line segment 80 overlap a same circuit column 200. Alternatively, as shown in FIG. 18, the sixth sub-segment 93 can overlap a same circuit column 200 as only the second line segment 80, and none of the sixth sub-segments 93 overlap a same circuit column 200 as the firstline segment 30.

FIG. 19A illustrates the relationship between multiple second sub-segments 13 and multiple circuit columns 200 in some embodiments of the present disclosure, at least two adjacent second sub-segments 13 respectively overlap adjacent circuit columns 200. FIG. 19B illustrates the relationship between multiple sixth sub-segments 93 and multiple circuit columns 200, and at least two adjacent sixth sub-segments 93 respectively overlap adjacent circuit columns 200.

Additionally, referring to FIGS. 17 and 19, FIG. 17 illustrates a case where at least two adjacent fourth sub-segments 72 overlap adjacent circuit columns 200, respectively. Of course, in other embodiments, based on FIG. 17, at least two adjacent fourth sub-segments 72 can overlap circuit columns 200 spaced apart from each other, respectively. Similarly, referring to FIGS. 18 and 19, it can be seen that FIG. 18 illustrates that at least two adjacent fourth sub-segments 72 overlap the circuit columns 200 spaced apart from each other, respectively. Of course, in other embodiments, based on FIG. 18, at least two adjacent fourth sub-segments 72 overlap adjacent circuit columns 200, respectively.

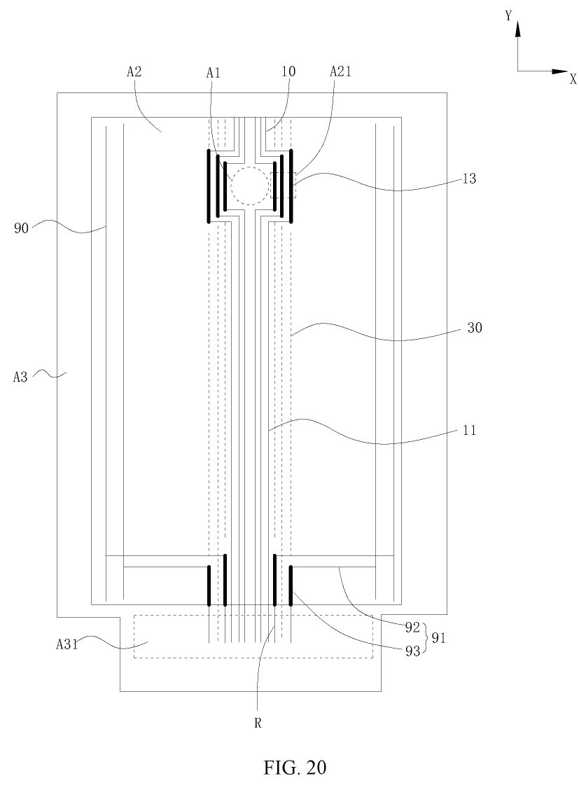

In some embodiments, referring to FIGS. 20-23, in the thickness direction Z of the display panel, at least two adjacent sixth sub-segments 93 respectively overlap the circuit columns 200 spaced apart from each other. FIGS. 20-23 illustrate only at least one of the sixth sub-segments 93 corresponding to the first line segment 30 and fail to illustrate the sixth sub-segment 93 corresponding to the first sub-segment 11 and the sixth sub-segments 93 corresponding to other trace structures. Additionally, taking the first signal line 10 being a data line configured to transmit the data signal data as an example, FIGS. 20-23 illustrate only at least one of the data lines including the second sub-segment 13 and fail to illustrate other data lines.

In the embodiments of the present disclosure, with respect to a case where the region in the second region A2 that is provided with the third detouring portion 91 can have a relatively large spatial dimension, the positions of adjacent sixth sub-segments 93 can be flexibly adjusted so that at least two adjacent sixth sub-segments 93 overlap the circuit columns 200 spaced apart from each other, thereby increasing the spacing between adjacent sixth sub-segments 93 and reducing the fabrication difficulty.

It should be noted that different display panels can have different wiring manners. On such basis, in a certain specific wiring manner, it can be chosen to set at least two adjacent sixth sub-segments 93 to overlap adjacent circuit columns 200, while in other wiring manners, it can be chosen to set at least two adjacent sixth sub-segments 93 to overlap circuit columns 200 spaced apart from each other, with which line detouring requirements of different display panels can be matched, thereby having a better flexibility.

In some embodiments, referring to FIGS. 1-3 and 20, the display panel further includes a first line segment 30 located in a same layer as and insulated from the second sub-segment 13 and the sixth sub-segment 93. The first line segment 30 extends in the second direction Y, and the first line segments 30 are located at two sides of the second sub-segment 13, respectively. Two adjacent first line segments 30 are a first trace 34 and a second trace 35, respectively. The first trace 34 is located at the side of the sixth sub-segment 93 facing towards the second sub-segment 13. The projections of the first trace 34 and the sixth sub-segment 93 in the thickness direction Z of the display panel overlap a same circuit column 200. The second trace 35 is located between adjacent sixth sub-segments 93 and extends to the fan-out region A31.

In the embodiments of the present disclosure, the projections of adjacent second sub-segments 13 overlap the projections of adjacent circuit columns 200, respectively, and the projections of adjacent sixth sub-segments 93 overlap the projections of circuit columns 200 spaced apart from each other. On such basis, the first line segment 30 can include two types of traces, i.e., the first trace 34 and the second trace 35. The projection of the first trace 34 overlaps the projection of a same circuit column 200 with the projection of the second sub-segment 13, and also overlaps the projection of a same circuit column 200 with the projection of the sixth sub-segment 93. Therefore, in the embodiments of the present disclosure, the first trace 34 is provided at the side of the sixth sub-segment 93 facing towards the second sub-segment 13 to meet the insulation requirements between the first trace 34 and the sixth sub-segment 93. For the second trace 35, since it is located between the sixth sub-segments 93, even if the second trace 35 extends into the fan-out region A31, it will not interfere with the sixth sub-segments 93. Thus, the second trace 35 can extend into the fan-out region A31 to increase its extending length and the reliability of corresponding signal transmission.

In some embodiments, the first trace 34 is configured to transmit the first power supply signal pvee, and the second trace 35 is configured to transmit the reset signal. In other words, the vertical trace configured to transmit the first power supply signal pvee does not extend into the fan-out region A31 to meet the disposing requirements of the sixth sub-segments 93, while the vertical trace configured to transmit the reset signal can extend into the fan-out region A31.

In the embodiments of the present disclosure, the sixth sub-segment 93 does not affect the extending path of the second trace 35, thereby allowing the second trace 35 to extend into the fan-out region A31 and overlap more pixel circuits 20 in a single circuit column 200, thereby improving the transmission reliability of the reset signal in the second trace 35.

It should be noted that FIGS. 20-23 illustrate various wiring manners in different types of display panels under the premise that at least two adjacent sixth sub-segments 93 overlap circuit columns 200 spaced apart from each other, respectively. Specifically, FIG. 20 illustrates a case where the display panel includes only one first region A1 and the first sub-region A21 is located at least one side of the first region A1 in the first direction. In this case, at least one of the sixth sub-segments 93 can overlap a same circuit column 200 with the first line segment 30.

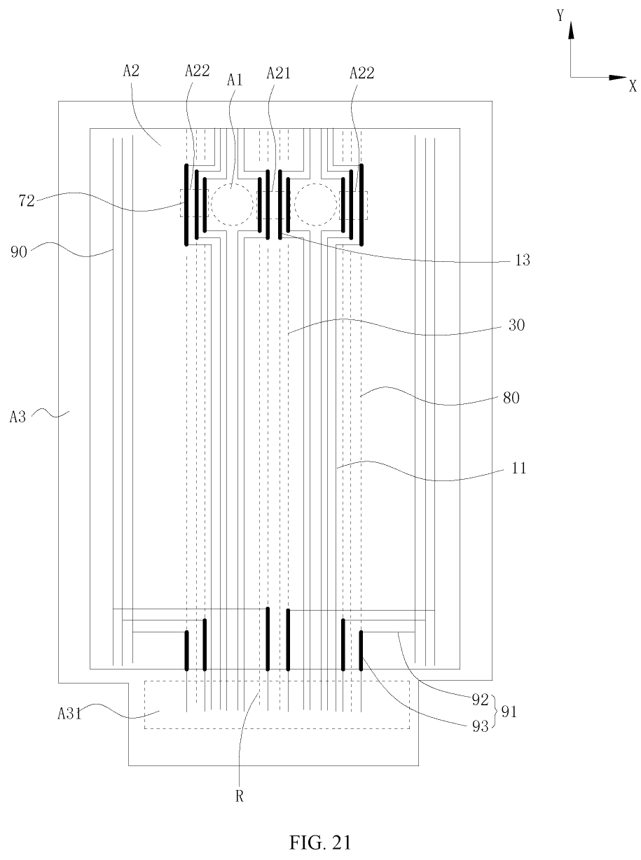

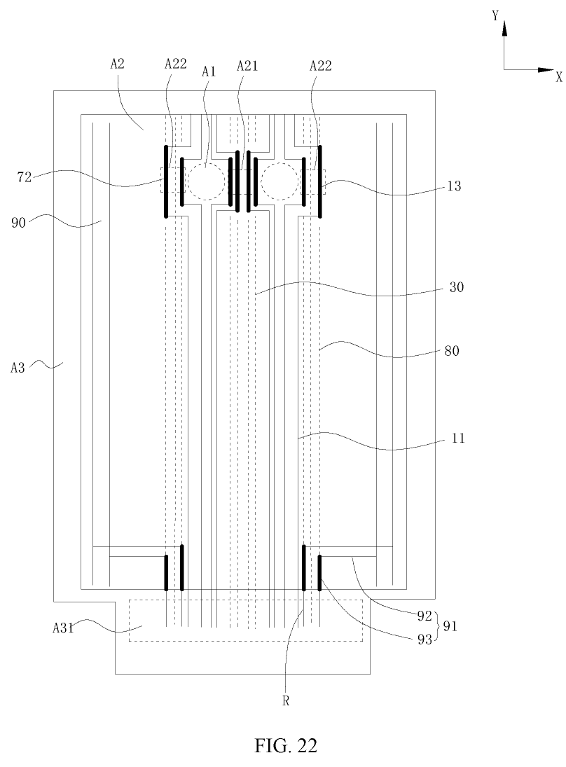

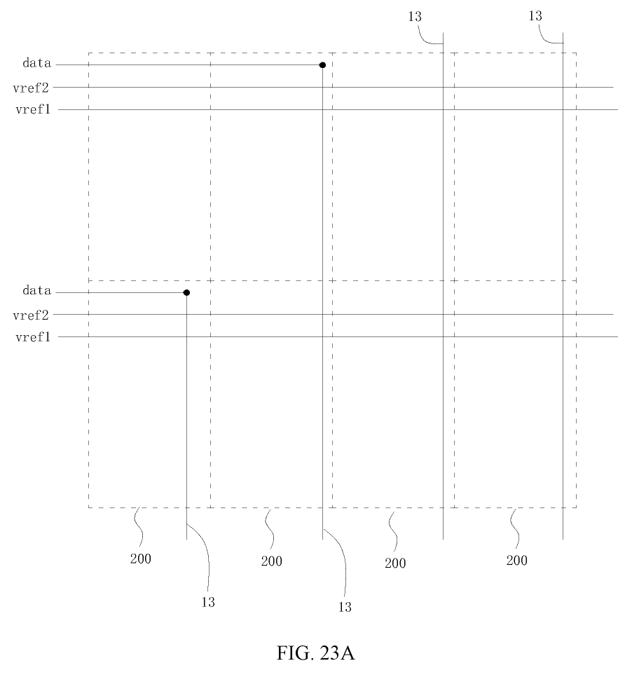

FIGS. 21 and 22 both illustrate a case where the display panel includes multiple first regions A1, the first sub-region A21 is located between adjacent first regions A1, and the second sub-region A22 is located on a same side of all first regions A1. In this case, all first line segments 30 can include a first trace 34 and a second trace 35, the first trace 34 is configured to transmit the first power supply signal pvee, and the second trace 35 is configured to transmit the reset signal.

Further, as shown in FIG. 21, at least one of the sixth sub-segments 93 and the first line segment 30 respectively overlap a same circuit column 200, and at least one of the sixth sub-segments 93 and the second line segment 80 respectively overlap a same circuit column 200. Alternatively, as shown in FIG. 22, all sixth sub-segments 93 can overlap a same circuit column 200 with only the second line segment 80, and none of the sixth sub-segments 93 overlaps a same circuit column 200 with the first line segment 30.

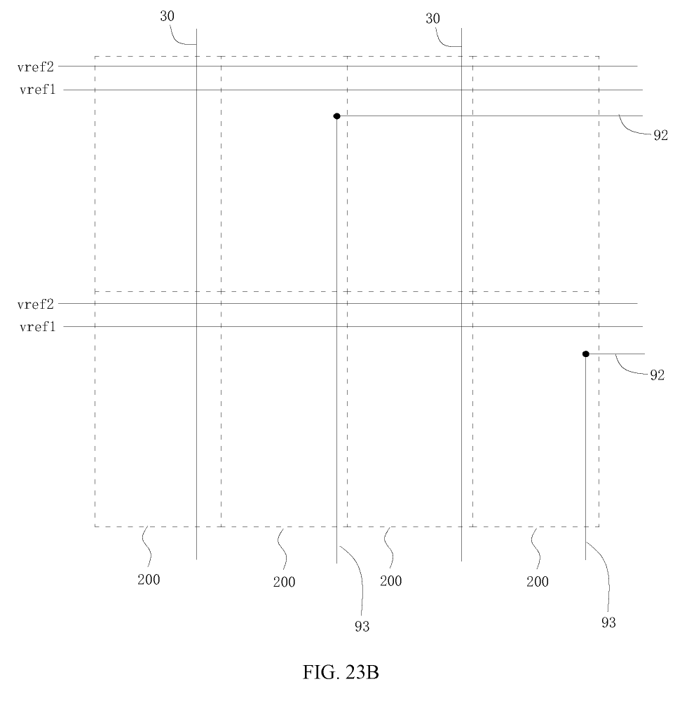

FIG. 23A illustrates the relationship between multiple second sub-segments 13 and multiple circuit columns 200 in some embodiments of the present disclosure, and at least two adjacent second sub-segments 13 respectively overlap adjacent circuit columns 200. FIG. 23B illustrates the relationship between multiple sixth sub-segments 93 and multiple circuit columns 200, and at least two adjacent sixth sub-segments 93 respectively overlap circuit columns 200 spaced apart from each other.

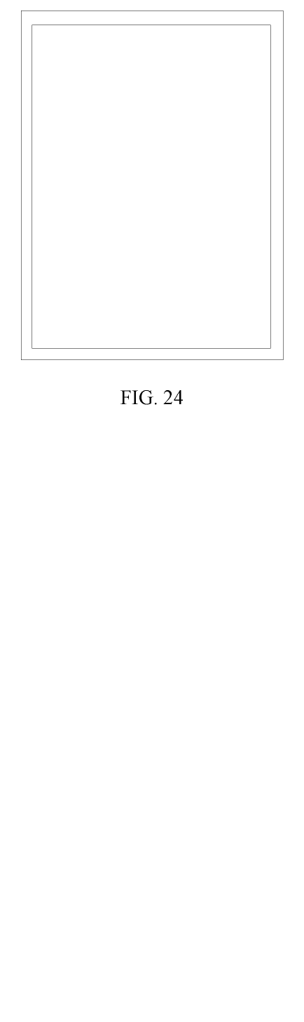

In addition, referring to FIGS. 21 and 23, it can be seen that FIG. 21 illustrates a case where at least two adjacent fourth sub-segments 72 overlap adjacent circuit columns 200, respectively. Of course, in other embodiments, based on FIG. 21, at least two adjacent fourth sub-segments 72 overlap circuit columns 200 spaced apart from each other, respectively. Similarly, in conjunction with FIGS. 23 and 24, it can be seen that FIG. 23 illustrates at least two adjacent fourth sub-segments 72 overlap the circuit columns 200 spaced apart from each other, respectively. Of course, in other embodiments, based on FIG. 19, at least two adjacent fourth sub-segments 72 overlap adjacent circuit columns 200, respectively.

In some embodiments, both the first signal line 10 and the fourth signal line 90 are configured to transmit the data signals data.

In the embodiments of the present disclosure, both the first signal line 10 and the fourth signal line 90 are vertical traces configured to transmit the data signals data, and the first signa8l line 10 needs to extend to detour round the first region A1, thereby the first signal line 10 including the first detouring portion 12 at the periphery of the first region A1. For the fourth signal line 90, to enable the fourth signal line 90 to receive the data signal data transmitted by the trace structure in the fan-out region A31, a third detouring portion 91 is added in the second region A2 realize the transmission of the data signal data through the third detouring portion 91. Further, for these two vertical traces configured to transmit the data signals, the embodiments of the present disclosure also adjusts other vertical traces so that only the signal trace corresponding to the first line segment 30 needs to be cut off to meet the disposing requirements of the detour line structures corresponding to the first signal line 10 and the fourth signal line 90, thereby simplifying the design and manufacturing difficulty of the internal wiring of the display panel.

In a second aspect, referring to FIG. 24, some embodiments of the present disclosure provide a display apparatus including the display panel provided in any one of the above implementations.

It should be noted that the display apparatus provided by the embodiments of the present disclosure has the beneficial effects of the display panel provided in any of one of the above implementations. Specific details can be referred to the above description of the beneficial effects of the display panel, which is not limited in the embodiments of the present disclosure. Additionally, in addition to the display panel, the display apparatus can include a mid-frame, which at least partially surrounds the periphery of the display panel to protect the display panel.

Although the implementations disclosed in present disclosure are described above, these contents are merely implementations adopted for the convenience of understanding present disclosure and is not intended to limit the present disclosure. Any skilled in the technical field to which the present disclosure pertains can make any modifications and changes in the form and details of the implementation without departing from the spirit and the scope disclosed in present disclosure. However, the protection scope of the present disclosure shall still be determined by the scope defined in the appended claims.

The above description presents merely specific implementations of the present disclosure. Those skilled in the art will clearly understand that, for convenience and brevity in description, the corresponding processes in the above method embodiments can be referred to for the replacements to other connection manners described above and so on, which will not be repeated herein. It should be understood that the protection scope of the present disclosure is not limited to the above. Any person skilled in the art can easily think of various equivalent modifications or replacements in the technical scope disclosed in present disclosure, and such modifications or replacements should all fall within the protection scope of present disclosure.

What is claimed is:

1. A display panel, having a first region and a second region, a transmittance of the first region being greater than a transmittance of the second region, the second region comprising a first sub-region adjacent to the first region in a first direction; and the display panel further comprising:
a first signal line disposed in the second region, the first signal line comprising first sub-segments located at two sides of the first region along a second direction and a first detouring portion connecting to the first sub-segments, the first detouring portion comprising a second sub-segment extending in the second direction and at least partially located in the first sub-region, and the first direction intersecting with the second direction; and
a pixel circuit, disposed in the second region, a plurality of the pixel circuits being arranged in an array in the first direction and the second direction, and a plurality of the pixel circuits arranged side by side in the second direction jointly constituting a circuit column,
wherein in a thickness direction of the display panel, at least parts of adjacent of the second sub-segments and at least parts of adjacent of the circuit columns overlap, respectively.

2. The display panel according to claim 1, further comprising first line segments in a same layer as the second sub-segment, and the first line segments being insulated from the second sub-segment, the first line segments extending along the second direction and located at both sides of the second sub-segment,
wherein in the thickness direction of the display panel, the second sub-segment and the first line segments overlap the same circuit column.

3. The display panel according to claim 2, wherein at least parts of the first line segments are configured to transmit first power supply signals.

4. The display panel according to claim 3, wherein the first line segments adjacent to each other in the first direction are configured to transmit the first power supply signals, and projections of the adjacent first line segments overlap projections of the adjacent circuit columns, respectively.

5. The display panel according to claim 3, wherein parts of the first line segments are configured to transmit reset signals, and the first line segments transmitting the first power supply signals and the first line segments transmitting the reset signals are alternately arranged in the first direction.

6. The display panel according to claim 5, wherein a plurality of the first line segments transmitting the reset signals comprise a first-type trace and a second-type trace, the first-type trace is configured to transmit a first reset signal, and the second-type trace is configured to transmit a second reset signal,
wherein the pixel circuit comprises a first reset transistor, a second reset transistor and a driving transistor, a first electrode of the first reset transistor is configured to receive the first reset signal, a second electrode of the first reset transistor is electrically connected to a control end of the driving transistor, a first electrode of the second reset transistor is configured to receive the second reset signal, and a second electrode of the second reset transistor is electrically connected to an anode.

7. The display panel according to claim 5, wherein a plurality of the first line segments transmitting the reset signals comprise a second-type trace and a third-type trace, the second-type trace is configured to transmit a second reset signal, and the third-type trace is configured to transmit a third reset signal,
wherein the pixel circuit comprises a second reset transistor, a third reset transistor, and a driving transistor, a first electrode of the second reset transistor is configured to receive the second reset signal, a second electrode of the second reset transistor is electrically connected to an anode, a first electrode of the third reset transistor is configured to receive the third reset signal, and a second electrode of the third reset transistor is electrically connected to a first electrode of the driving transistor.

8. The display panel according to claim 6, wherein the first detouring portion further comprises a third sub-segment extending along the first direction, an end of the third sub-segment is connected to the first sub-segment, and another end of the third sub-segment is connected to the second sub-segment;
the display panel comprises a substrate, a first conductor layer disposed at a side of the substrate, and a second conductor layer located at a side of the first conductor layer away from the substrate, the third sub-segment is located in the first conductor layer, and the first sub-segments, the second sub-segment, and the first line segments are all located in the second conductor layer.

9. The display panel according to claim 8, further comprising a first reset signal line and a second reset signal line that extend along the first direction, wherein the first reset signal line transmits the first reset signal and electrically connects parts of the first line segments, the second reset signal line transmits the second reset signal and electrically connects parts of the first line segments, and the first reset signal line and the second reset signal line are in a same layer and are located at a side of the first conductor layer facing the substrate; or
the display panel further comprises the second reset signal line and a third reset signal line that extend along the first direction, the second reset signal line transmits the second reset signal and electrically connects parts of the first line segments, the third reset signal line transmits a third reset signal and electrically connects parts of the first line segments, and the second reset signal line and the third reset signal line are in a same layer and are located at the side of the first conductor layer facing the substrate.

10. The display panel according to claim 1, wherein the pixel circuit comprises a driving transistor, a distance between the adjacent second sub-segments along the first direction is D1, and a distance between the two driving transistors in the two adjacent pixel circuits along the first direction is D2, where D2 > D1.

11. The display panel according to claim 1, wherein a plurality of the first regions are provided and are arranged at intervals along the first direction, and the first sub-region is arranged between the adjacent first regions.

12. The display panel according to claim 1, further comprising a light-emitting unit, wherein the pixel circuit located in the first sub-region is electrically connected to the light-emitting unit; and/or,
the light-emitting unit located in the first region is electrically connected to the pixel circuit in the first sub-region.

13. The display panel according to claim 1, wherein the second region further comprises a second sub-region, the second sub-region is located at a side of the first region in the first direction, and the first sub-region and the second sub-region do not overlap with each other;
the display panel further comprises a third signal line arranged in the second region, the third signal line extends along the second direction and comprises a second detouring portion, the second detouring portion comprises a fourth sub-segment extending along the second direction and located in the second sub-region,
wherein in the thickness direction of the display panel, adjacent two of the fourth sub-segments overlap two of the circuit columns arranged at intervals; or, the adjacent fourth sub-segments overlap the adjacent circuit columns.

14. The display panel according to claim 13, further comprising a second line segment in a same layer as the fourth sub-segment, and the second line segment being insulated from the fourth sub-segment, wherein the second line segment extends along the second direction and is located between the adjacent fourth sub-segments,
wherein in the thickness direction of the display panel, the second line segment and the fourth sub-segment overlap different ones of the circuit columns, respectively.

15. The display panel according to claim 14, wherein at least parts of the second line segments are configured to transmit first power supply signals; and/or,
at least parts of the second line segments are configured to transmit reset signals.

16. The display panel according to claim 1, further comprising a third region arranged around the second region, the third region comprising a fan-out region located at a side of the second region along the second direction,
wherein the display panel further comprises a fourth signal line, located at any side of the first region along the first direction, the fourth signal line is electrically connected to a fan-out line located in the fan-out region through a third detouring portion, the third detouring portion is located in the second region, and the third detouring portion comprises a fifth sub-segment extending along the first direction and a sixth sub-segment extending along the second direction.

17. The display panel according to claim 16, wherein in the thickness direction of the display panel, at least parts of the adjacent sixth sub-segments and the adjacent circuit columns are overlapped.

18. The display panel according to claim 16, further comprising a first line segment that is in a same layer as and insulated from the second sub-segment and the sixth sub-segment, wherein the first line segments extend along the second direction and are located at both sides of the second sub-segment,
wherein the first line segments are all located at a side of the sixth sub-segment facing the second sub-segment, and in the thickness direction of the display panel, the first line segment and the sixth sub-segment each overlap the same circuit column.

19. The display panel according to claim 16, wherein the first signal line and the fourth signal line are both configured to transmit data signals.

20. A display apparatus, comprising a display panel having a first region and a second region, a transmittance of the first region being greater than a transmittance of the second region, the second region comprising a first sub-region adjacent to the first region in a first direction; and the display panel further comprising: a first signal line disposed in the second region, the first signal line comprising first sub-segments located at two sides of the first region along a second direction and a first detouring portion connecting to the first sub-segments, the first detouring portion comprising a second sub-segment extending in the second direction and at least partially located in the first sub-region, and the first direction intersecting with the second direction; and a pixel circuit, disposed in the second region, a plurality of the pixel circuits being arranged in an array in the first direction and the second direction, and a plurality of the pixel circuits arranged side by side in the second direction jointly constituting a circuit column, wherein in a thickness direction of the display panel, at least parts of adjacent of the second sub-segments and at least parts of adjacent of the circuit columns overlap, respectively.
